(19) United States
(12) Patent Application Publication
(10) Pub. No.: US 2026/0033084 A1
(43) Pub. Date: Jan. 29, 2026

(54) DISPLAY APPARATUS

(71) Applicant: LG Display Co., Ltd., Seoul (KR)

(72) Inventors: Jae Yong YUN, Paju-si (KR); Kyoung June JUNG, Paju-si (KR); Jae Kwang LEE, Paju-si (KR)

(73) Assignee: LG Display Co., Ltd., Seoul (KR)

(21) Appl. No.: 19/253,586

(22) Filed: Jun. 27, 2025

(30) Foreign Application Priority Data
Jul. 24, 2024 (KR) 10-2024-0097808

(51) Int. Cl. H10H 29/49; H01L 25/16; H10H 29/37; H10H 29/855

(52) U.S. Cl. CPC H10H 29/49; H01L 25/167; H10H 29/37; H10H 29/8552

(57) ABSTRACT

A display apparatus according to an embodiment of the present specification may include a substrate including a display area including a plurality of pixels and a non-display area disposed around the display area, one or more pixel driving circuits disposed on the substrate, a plurality of inorganic light emitting diodes connected to the one or more pixel driving circuits, an optical layer disposed around the plurality of inorganic light emitting diodes, a first passivation layer disposed on the optical layer, and a trench disposed between the plurality of inorganic light emitting diodes.

### CROSS-REFERENCE TO RELATED APPLICATION

This application claims priority to and the benefit of Korean Patent Application No. 10-2024-0097808, filed on Jul. 24, 2024, the disclosure of which is incorporated herein by reference in its entirety.

### BACKGROUND

### 1. Field of the Disclosure

The present specification relates to a display apparatus.

### 2. Discussion of Related Art

Display apparatuses are applied to various electronic devices such as a TV, a mobile phone, a laptop, and a tablet.

Display apparatuses include an organic light emitting display (OLED) or the like that emits light by itself and a liquid crystal display (LCD) or the like that needs a separate light source.

In recent years, a display apparatus including a light emitting diode (LED) has gained attention as a next-generation display apparatus. Due to being made of an inorganic material rather than an organic material, an LED has a faster lighting speed, has higher luminous efficiency, and can display an image with higher brightness compared to an LCD or an OLED.

### SUMMARY

The reliability of a display apparatus including an organic light emitting diode (LED) (for example, a micro LED) may be reduced due to moisture or the like penetrating from the outside.

Embodiments of the present specification are directed to providing a display apparatus with improved reliability.

Objectives of embodiments of the present specification are not limited to the above-mentioned objective, and other unmentioned objectives should be clearly understood by those of ordinary skill in the art from the description below.

A display apparatus according to an example embodiment of the present specification may include a substrate including a display area including a plurality of pixels and a non-display area present around the display area, one or more pixel driving circuits disposed on the substrate, a plurality of inorganic light emitting diodes connected to the one or more pixel driving circuits, an optical layer present around the plurality of inorganic light emitting diodes, a first passivation layer disposed on the optical layer, and a trench disposed between the plurality of inorganic light emitting diodes.

In another aspect, a display apparatus according to various example embodiments of the present specification may include a display panel made of a plurality of pixels including a plurality of light emitting diodes and a trench present on the plurality of pixels. The trench may include a first trench disposed between the plurality of light emitting diodes and a second trench disposed between the plurality of light emitting diodes.

In yet another aspect, a display apparatus according to various example embodiments of the present specification may include a substrate including a display area and a non-display area present around the display area, a plurality of light emitting diodes present in the display area, a plurality of dummy light emitting diodes present in the non-display area, a first passivation layer disposed on the plurality of light emitting diodes and the plurality of dummy light emitting diodes, and a trench present in the non-display area and disposed between the plurality of dummy light emitting diodes.

Detailed matters according to various example embodiments of the present specification are included in the following description and the accompanying drawings. It is to be understood that both the foregoing general description and the following detailed description are by way of example and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure. In the drawings:

FIG. 1 is an exploded perspective view of a display apparatus according to an example embodiment of the present specification;

FIG. 2 is a plan view illustrating the display apparatus according to an example embodiment of the present specification;

FIG. 3 is a plan view illustrating the display apparatus according to an example embodiment of the present specification;

FIG. 4 is a plan view illustrating the display apparatus according to an example embodiment of the present specification;

FIG. 5 is a plan view illustrating the display apparatus according to an example embodiment of the present specification;

FIG. 6 is a plan view illustrating the display apparatus according to an example embodiment of the present specification;

FIG. 7 is a plan view illustrating the display apparatus according to an example embodiment of the present specification;

FIG. 8 is a plan view illustrating the display apparatus according to an example embodiment of the present specification;

FIG. 9 is a plan view illustrating the display apparatus according to an example embodiment of the present specification;

FIG. 10 is a plan view illustrating the display apparatus according to an example embodiment of the present specification;

FIG. 11 is a plan view illustrating the display apparatus according to an example embodiment of the present specification;

FIG. 12 is a plan view illustrating the display apparatus according to an example embodiment of the present specification;

FIG. 13 is a plan view illustrating the display apparatus according to an example embodiment of the present specification;

FIG. 14 is a plan view illustrating the display apparatus according to an example embodiment of the present specification;

FIG. 15 is a plan view illustrating the display apparatus according to an example embodiment of the present specification;

FIG. 16 is a plan view illustrating the display apparatus according to an example embodiment of the present specification;

FIG. 17 is a plan view illustrating the display apparatus according to an example embodiment of the present specification;

FIG. 18 is an enlarged view illustrating the display apparatus according to an example embodiment of the present specification;

FIG. 19 is a view illustrating a circuit structure according to an example embodiment of the present specification;

FIG. 20 is a cross-sectional view illustrating the display apparatus according to an example embodiment of the present specification;

FIG. 21 is a cross-sectional view illustrating the display apparatus according to an example embodiment of the present specification;

FIG. 22 is a cross-sectional view illustrating the display apparatus according to an example embodiment of the present specification;

FIG. 23 is a cross-sectional view illustrating the display apparatus according to an example embodiment of the present specification;

FIG. 24 is a cross-sectional view illustrating the display apparatus according to an example embodiment of the present specification;

FIG. 25 is a cross-sectional view illustrating the display apparatus according to an example embodiment of the present specification;

FIG. 26 is a cross-sectional view illustrating the display apparatus according to an example embodiment of the present specification;

FIG. 27 is a cross-sectional view illustrating the display apparatus according to an example embodiment of the present specification;

FIG. 28 is a cross-sectional view illustrating the display apparatus according to an example embodiment of the present specification;

FIG. 29 is a cross-sectional view illustrating the display apparatus according to an example embodiment of the present specification;

FIG. 30 is a cross-sectional view illustrating the display apparatus according to an example embodiment of the present specification;

FIG. 31 is a cross-sectional view illustrating the display apparatus according to an example embodiment of the present specification;

FIG. 32 is a cross-sectional view illustrating the display apparatus according to an example embodiment of the present specification;

FIG. 33 is a cross-sectional view illustrating the display apparatus according to an example embodiment of the present specification;

FIG. 34 is a cross-sectional view illustrating the display apparatus according to an example embodiment of the present specification;

FIG. 35 is a cross-sectional view illustrating the display apparatus according to an example embodiment of the present specification;

FIG. 36 is a cross-sectional view illustrating the display apparatus according to an example embodiment of the present specification;

FIG. 37 is a cross-sectional view illustrating the display apparatus according to an example embodiment of the present specification;

FIG. 38 is a cross-sectional view illustrating the display apparatus according to an example embodiment of the present specification;

FIG. 39 is a view illustrating a device to which the display apparatus according to example embodiments of the present specification can be applied;

FIG. 40 is a view illustrating a device to which the display apparatus according to example embodiments of the present specification can be applied;

FIG. 41 is a view illustrating a device to which the display apparatus according to example embodiments of the present specification can be applied; and

FIG. 42 is a view illustrating a device to which the display apparatus according to example embodiments of the present specification can be applied.

### DETAILED DESCRIPTION

The advantages and features of the present disclosure, and methods of achieving them will be apparent from the example embodiments described in detail below in conjunction with the accompanying drawings. However, the present disclosure is not limited to the following embodiments disclosed herein, but may be implemented in various different forms. The following example embodiments are provided to make the disclosure of the present specification more complete and to enable those skilled in the art to fully comprehend the scope of the present disclosure.

The shapes, sizes, proportions, angles, numbers, and the like of elements shown in the drawings to illustrate embodiments of the present specification are merely illustrative and are not intended to be limiting. Identical reference numerals may designate identical components throughout the description. Further, in describing the present specification, detailed descriptions of related known technologies may be omitted so as not to obscure the essence or features of the present specification. Terms such as “comprising,” “including,” or “having,” as used herein, are generally intended to allow for the addition of other components, unless the terms are used with a more limiting term like “only.” References to components of a singular noun include the plural of that noun, and vice versa, unless specifically stated otherwise.

In the interpretation of components, they are construed to include margins of error, even if this is not explicitly stated.

Where a positional relationship is described, for example, using terms such as “on top of,” “above,” “below,” or “next to” to describe the positional relationship of two parts, one or more other parts may be located between the two parts, unless a more limiting term like “immediately” or “directly” is used.

Where a temporal relationship is described, for example, using terms such as “after,” “following,” “next to,” or “before” to describe a temporal antecedent or consequent relationship, it may not be limited to being continuous unless a more limiting term like “immediately” or “directly” is used.

Terms like “the first”, “the second”, and so on may be used to describe various components, but these components are not limited by these terms. These terms are used only to refer to one component separately from another. Therefore, the first component referred to below may be a second component, and vice versa, within the technical spirit of the present specification.

Terms such as first, second, A, B, (a), or (b) may be used to describe elements of the embodiments of the present specification. Such terms are intended only to refer to one component separately from another and are not intended to define the nature, sequence, order, or number of such components. Where a component is described as “connected,” “coupled,” or “attached” to another component, it is to be understood that the component may be directly connected or attached to the other component, but that there may also be other components “interposed” between the respective components which may be indirectly connected or attached where not specifically stated.

It should be understood that the term “at least one” includes all possible combinations of one or more related components. For example, the meaning of “at least one of the first, second, and third components” can be understood to include not only the first, second, or third component, but also any combination of two or more of the first, second, and third components.

Each of the features of various embodiments described herein may be coupled or combined with one another in whole or in part, and may be technologically interlocked and operated in various ways, and each of the embodiments may be carried out independently or in conjunction with one another.

Hereinafter, various example embodiments of the present disclosure are illustrated by way of the accompanying drawings and examples. The scale of the components depicted in the drawings may be different from the actual scale for convenience of explanation and is not limited to the scale depicted in the drawings.

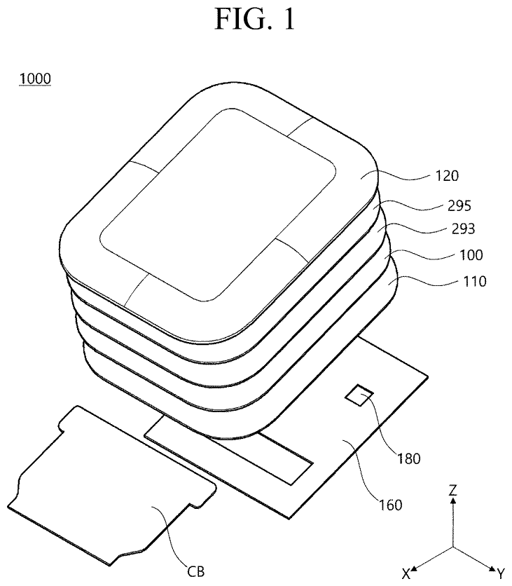

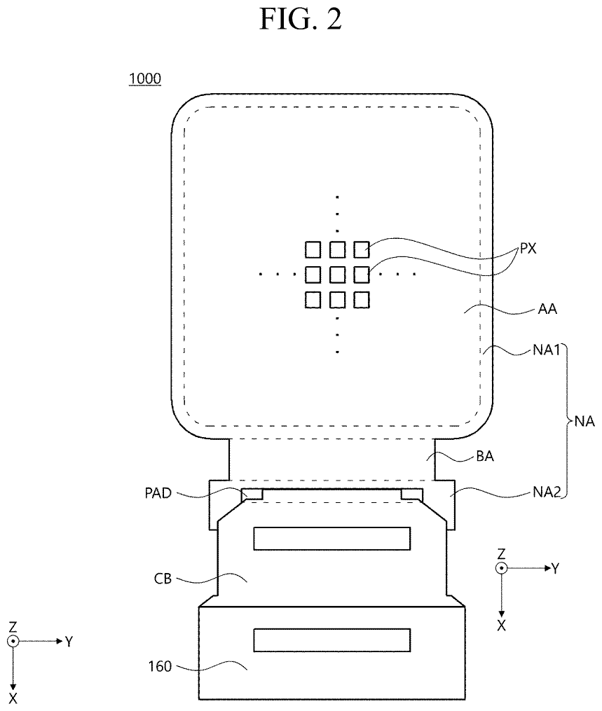

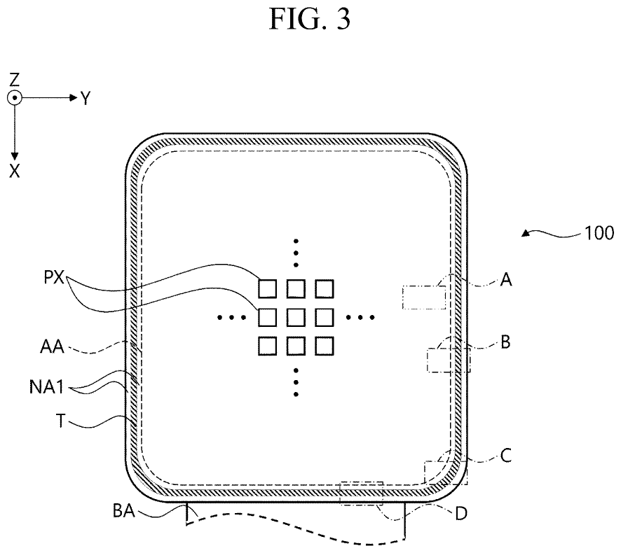

FIG. 1 is an exploded perspective view illustrating a display apparatus according to an example embodiment of the present specification. FIG. 2 is a plan view illustrating the display apparatus according to an example embodiment of the present specification. FIG. 3 is a plan view illustrating the display apparatus according to an example embodiment of the present specification. FIG. 18 is an enlarged view illustrating the display apparatus according to an example embodiment of the present specification.

As shown in FIGS. 1, 2, and 18, a display apparatus 1000 according to an embodiment of the present specification may include a display panel 100, a polarizing layer 293, an adhesive layer 295, a cover member 120, a support substrate 110, a flexible circuit board CB, and a printed circuit board 160.

For example, the display apparatus 1000 may include a substrate 110. The substrate 110 may be a member supporting other components of the display apparatus 1000. The substrate 110 may be made of an insulating material. For example, the substrate 110 may be made of glass, resin, or the like. In addition, the substrate 110 may be made of a material having flexibility. For example, the substrate 110 may be made of a plastic material having flexibility such as polyimide (PI). However, embodiments of the present specification are not limited thereto.

The display panel 100 may implement information, a video, and/or an image provided to a user. For example, the display panel 100 may include a display area AA and a non-display area NA. For example, the substrate 110 may include the display area AA and the non-display area NA. The display area AA and the non-display area NA may be described for the display apparatus 1000 as a whole instead of being described only for the substrate 110.

The display area AA may be an area in which an image is displayed. The display area AA may include a plurality of pixels PX. The plurality of pixels PX may each be made of a plurality of subpixels. The plurality of subpixels may each have a plurality of light emitting diodes disposed thereon. The plurality of light emitting diodes may be configured differently according to the type of the display apparatus 1000. For example, when the display apparatus 1000 is an inorganic light emitting display apparatus, the light emitting diodes may be inorganic light-emitting diodes (LEDs), micro light-emitting diodes (micro LEDs), or mini light-emitting diodes (mini LEDs), but embodiments of the present specification are not limited thereto.

The non-display area NA may be an area in which an image is not displayed. The non-display area NA may be present around the display area AA or may surround the display area AA. Various lines, circuits, and the like for driving the plurality of pixels PX of the display area AA may be disposed in the non-display area NA. For example, various lines and driving circuits may be mounted in the non-display area NA, and a pad portion PAD to which an integrated circuit, a printed circuit, and the like are connected may be disposed in the non-display area NA, but the embodiments of the present specification are not limited thereto.

For example, a driving circuit may be a data driving circuit and/or a gate driving circuit, but the embodiments of the present specification are not limited thereto. Lines to which a control signal for controlling driving circuits is supplied may be disposed on the display panel 100. For example, the control signal may include various timing signals including a clock signal, an input data enable signal, and synchronization signals, but the embodiments of the present specification are not limited thereto. The control signal may be received through the pad portion PAD. For example, link lines LL for transmitting a signal may be disposed in the non-display area NA. For example, a driving part such as the flexible circuit board CB and the printed circuit board 160 may be connected to the pad portion PAD.

According to the present specification, the non-display area NA may include a first non-display area NA1, a bending area BA, and a second non-display area NA2. For example, the first non-display area NA1 may be an area surrounding at least a portion of the display area AA. The bending area BA may be a bendable area that extends from at least any one side among a plurality of sides of the first non-display area NA1. The second non-display area NA2 may be an area extending from the bending area BA, and the pad portion PAD may be disposed in the second non-display area NA2. For example, the bending area BA may be in a bent state, and the remaining areas of the substrate 110 except for the bending area BA may be in a flat state. In this case, as the bending area BA is bent, the second non-display area NA2 may be located on a back surface of the display area AA. However, the embodiments of the present specification are not limited thereto.

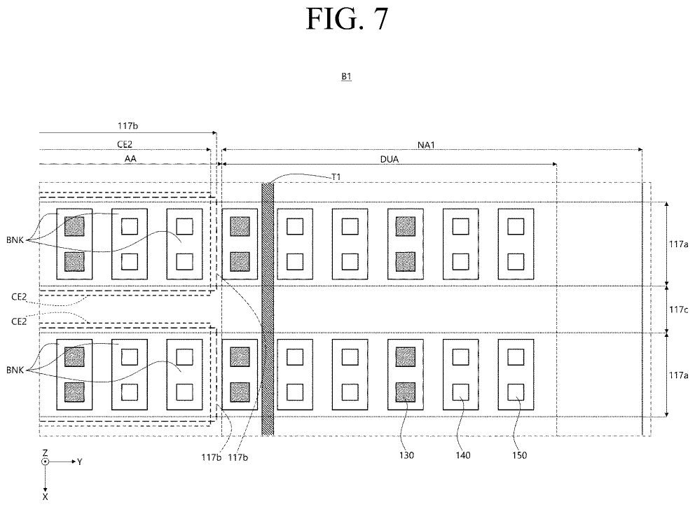

A trench T of FIG. 3 will be described later with reference to FIGS. 7 to 17.

The display area AA of the substrate 110 or the display apparatus 1000 may be configured in various shapes according to the design of the display apparatus 1000. For example, the display area AA may be configured in a rectangular shape with four round corners, but the embodiments of the present specification are not limited thereto. In another example, the display area AA may be configured in a rectangular shape with four right-angled corners or a circular shape, but the embodiments of the present specification are not limited thereto.

According to the present specification, a width of the second non-display area NA2 in which a plurality of pad electrodes PE are disposed may be wider than a width of the bending area BA in which only the plurality of link lines LL are disposed. In addition, a width of the display area AA in which the plurality of subpixels are disposed may be wider than the width of the bending area BA in which only the plurality of link lines LL are disposed. Although the width of the bending area BA is illustrated as being narrower than the widths of other areas of the substrate 110 in the drawings, the shape of the substrate 110 including the bending area BA is only illustrative, and the embodiments of the present specification are not limited thereto.

As shown in FIG. 18, a plurality of pixel driving circuits PD may be disposed in the display area AA. The plurality of pixel driving circuits PD may be circuits for driving the light emitting diodes of the plurality of subpixels. The plurality of pixel driving circuits PD may each include a plurality of transistors including a driving transistor, a storage capacitor, and the like and may supply a control signal, power, and driving current to the light emitting diodes of the plurality of subpixels to control a light emitting operation of the plurality of light emitting diodes. For example, the pixel driving circuit PD may include a power line and a signal line for controlling light emission on/off and/or light emission time of the light emitting diodes. For example, the plurality of pixel driving circuits PD may be driving drivers manufactured using a metal-oxide-semiconductor field effect transistor (MOSFET) manufacturing process on a semiconductor substrate, but the embodiments of the present specification are not limited thereto. A driving driver may include the plurality of pixel driving circuits PD and may drive the plurality of subpixels.

As shown also in FIG. 1, the flexible circuit board CB and the printed circuit board 160 may be disposed at a lower portion of the display panel 100. The flexible circuit board CB and the printed circuit board 160 may be disposed at least on one side edge of the display panel 100, but the embodiments of the present specification are not limited thereto. One side of the flexible circuit board CB may be attached to the display panel 100 and the other side thereof may be attached to the printed circuit board 160, but the embodiments of the present specification are not limited thereto. The flexible circuit board CB may be a flexible film, but the embodiments of the present specification are not limited thereto.

The pad portion PAD including the plurality of pad electrodes PE may be disposed in the second non-display area NA2. Driving parts including one or more flexible circuit boards (or flexible films) CB and the printed circuit board 160 may be attached or bonded to the pad portion PAD. The plurality of pad electrodes PE of the pad portion PAD may be electrically connected to the one or more flexible circuit boards (or flexible films) CB and may transmit various signals (or power) from the printed circuit board 160 and the flexible circuit board (or flexible film) CB to the plurality of pixel driving circuits PD of the display area AA.

The flexible circuit board (or flexible film) CB may be a film in which various parts are disposed on a base film having flexibility. For example, a driving integrated circuit (IC) such as a gate driver IC or a data driver IC may be disposed on the flexible circuit board (or flexible film) CB, but the embodiments of the present specification are not limited thereto. The driving IC may be a part that processes data and driving signals for displaying an image. The driving IC may be disposed in a manner such as a chip-on-glass (COG) manner, a chip-on-film (COF) manner, or a tape carrier package (TCP) manner according to a manner in which the driving IC is mounted, but the embodiments of the present specification are not limited thereto. The flexible circuit board (or flexible film) CB may be attached or bonded onto the plurality of pad electrodes PE through a conductive adhesive layer, but the embodiments of the present specification are not limited thereto.

The printed circuit board 160 may be a part that is electrically connected to the one or more flexible circuit boards (or flexible films) CB and supplies a signal to the driving IC. The printed circuit board 160 may be disposed on one side of the flexible circuit board (or flexible film) CB and may be electrically connected to the flexible circuit board (or flexible film) CB. Various parts for supplying various signals to the driving IC may be disposed on the printed circuit board 160. For example, various parts such as a timing controller, a power supply, a memory, or a processor may be disposed on the printed circuit board 160. For example, the printed circuit board 160 may include a power management integrated circuit (PMIC), but the embodiments of the present specification are not limited thereto.

The printed circuit board 160 may include at least one hole 180, but the embodiments of the present specification are not limited thereto. An internal component that detects ambient light that may be provided to a plurality of sensors, a temperature, or the like may be disposed in an area that corresponds to the at least one hole 180. For example, the internal component may include an ambient light sensor (ALS), a temperature sensor, or the like, but the embodiments of the present specification are not limited thereto. For example, the hole 180 may be a through-hole or the like, but the embodiments of the present specification are not limited thereto.

As shown in FIG. 1, the polarizing layer 293 may be disposed on the display panel 100. The polarizing layer 293 may prevent or reduce a phenomenon in which light generated from an external light source enters the display panel 100 and affects the light emitting diodes or the like.

The cover member 120 may be disposed on the polarizing layer 293. The cover member 120 may be a member for protecting the display panel 100. The adhesive layer 295 may be disposed between the polarizing layer 293 and the cover member 120. The cover member 120 may be attached to the display panel 100 by the adhesive layer 295. The adhesive layer 295 may include an optically cleared adhesive (OCA), an optically cleared resin (OCR), a pressure sensitive adhesive (PSA), or the like, but the embodiments of the present specification are not limited thereto.

The support substrate 110 may be disposed between the display panel 100 and the printed circuit board 160. The support substrate 110 may reinforce the rigidity of the display panel 100. The support substrate 110 may be a back plate, but the embodiments of the present specification are not limited thereto.

As shown in FIGS. 1, 2, and 18, the plurality of link lines LL may be disposed in the non-display area NA. The plurality of link lines LL may be lines that transmit various signals from the one or more flexible circuit boards (or flexible films) CB and the printed circuit board 160 to the display area AA. The plurality of link lines LL may extend from the plurality of pad electrodes PE of the second non-display area NA2 toward the bending area BA and the first non-display area NA1 and may be electrically connected to a plurality of driving lines VL of the display area AA. The plurality of pixel driving circuits PD may be driven by receiving a signal from the one or more flexible circuit boards (or flexible films) CB and the printed circuit board 160 through the driving lines VL of the display area AA and the link lines LL of the non-display area NA. The plurality of connection lines LL may be spaced from each other and disposed on the same layer.

For example, the plurality of driving lines VL may be lines for transmitting a signal output from the flexible circuit board (or flexible film) CB and the printed circuit board 160 to the plurality of pixel driving circuits PD together with the plurality of link lines LL. The plurality of driving lines VL may be disposed in the display area AA and may each be electrically connected to one of the plurality of pixel driving circuits PD. The plurality of driving lines VL may extend from the display area AA toward the non-display area NA and may be electrically connected to the plurality of link lines LL. Accordingly, the signal output from the flexible circuit board (or flexible film) CB and the printed circuit board 160 may be transmitted to each of the plurality of pixel driving circuits PD through the plurality of link lines LL and the plurality of driving lines VL.

As the bending area BA is bent, one portion of the plurality of link lines LL may also be bent. Stress may be concentrated to the one portions of the link lines LL that is bent, and accordingly, cracks may be formed in the link lines LL. Thus, the plurality of link lines LL may be made of a conductive material with excellent flexibility to reduce cracks when the bending area BA is bent. For example, the plurality of link lines LL may be made of a conductive material with excellent flexibility such as gold (Au), silver (Ag), and aluminum (Al), but the embodiments of the present specification are not limited thereto. In addition, the plurality of link lines LL may also be made of one of various conductive materials used in the display area AA. For example, the plurality of link lines LL may be made of molybdenum (Mo), chromium (Cr), titanium (Ti), nickel (Ni), neodymium (Nd), copper (Cu), an alloy of silver (Ag) and magnesium (Mg), or an alloy thereof, but the embodiments of the present specification are not limited thereto. The plurality of link lines LL may be made of a multilayer structure including various conductive materials. For example, the plurality of link lines LL may be made of a triple layer structure of titanium (Ti)/aluminum (Al)/titanium (Ti), but the embodiments of the present specification are not limited thereto.

The plurality of link lines LL may be configured in various shapes to reduce stress. At least one portion of the plurality of link lines LL disposed on the bending area BA may extend in the same direction as an extending direction of the bending area BA or may extend in a different direction from the extending direction of the bending area BA to reduce stress. For example, in a case in which the bending area BA extends in one direction from the first non-display area NA1 toward the second non-display area NA2, at least one portion of the link lines LL disposed on the bending area BA may extend in a direction inclined from the one direction. In another example, at least one portion of the plurality of link lines LL may be configured in patterns of various shapes. For example, at least one portion of the plurality of link lines LL disposed on the bending area BA may have a shape in which a conductive pattern having at least one of a diamond shape, a rhombic shape, a trapezoidal wave shape, a triangular wave shape, a sawtooth wave shape, a sinusoidal wave shape, a circular shape, and an omega (Q) shape is repeatedly arranged, but the embodiments of the present specification are not limited thereto. Accordingly, to minimize or reduce the stress concentrated to the plurality of link lines LL and cracks caused thereby, the plurality of link lines LL may be formed in various shapes including the above-listed shapes, but the embodiments of the present specification are not limited thereto.

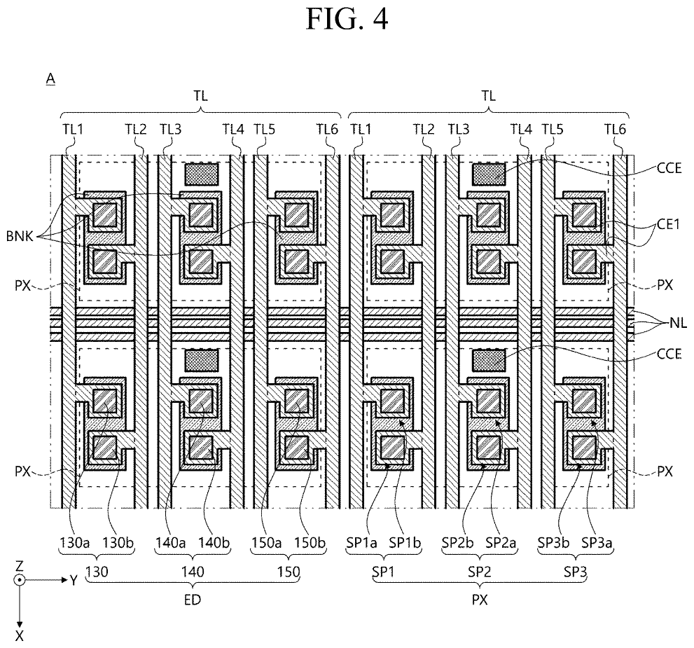

FIGS. 4 to 6 are plan views illustrating the display apparatus according to an example embodiment of the present specification.

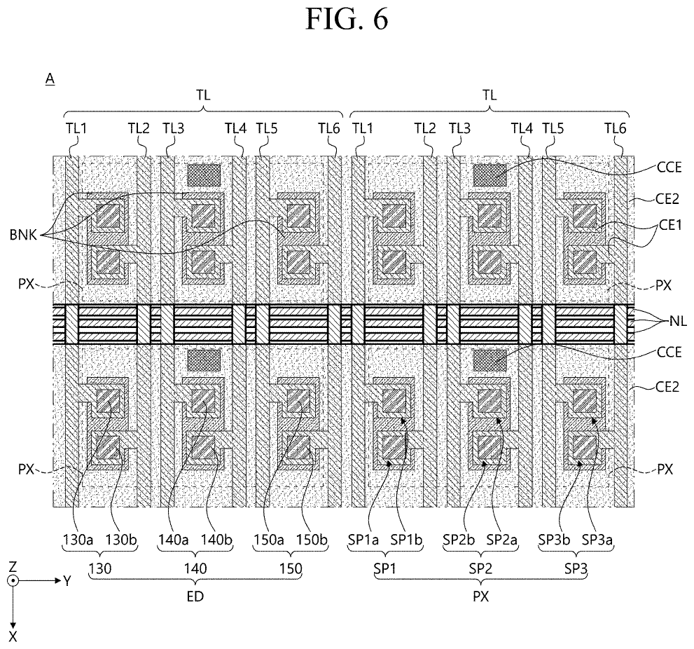

FIGS. 4 and 6 are enlarged views of a display area including a plurality of pixels. FIGS. 4 and 6 are partially enlarged views showing portion A of FIG. 3 in an enlarged manner.

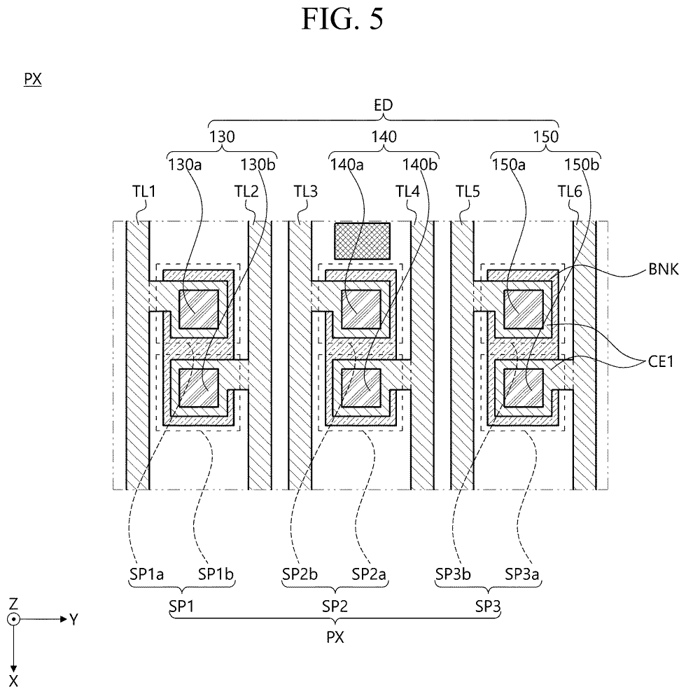

FIG. 5 is an enlarged view of a display area including a single pixel. FIG. 5 is a partially enlarged view showing a single pixel PX in an enlarged manner.

Although only a plurality of signal lines TL, a plurality of communication lines NL, a plurality of first electrodes CE1, a plurality of banks BNK, and a plurality of light emitting diodes ED are illustrated in FIGS. 4 and 5, the embodiments of the present specification are not limited thereto. FIG. 6 is an enlarged plan view resulting from additionally placing a plurality of second electrodes CE2 in FIG. 4.

As shown in FIGS. 4 and 5, a plurality of pixels PX made of a plurality of subpixels may be disposed in a display area AA. The plurality of subpixels may each include a light emitting diode ED and may independently emit light. The plurality of subpixels may be arranged in a matrix form while forming a plurality of rows and a plurality of columns, but the embodiments of the present specification are not limited thereto.

The plurality of subpixels may include a first subpixel SP1, a second subpixel SP2, and a third subpixel SP3. For example, any one of the first subpixel SP1, the second subpixel SP2, and the third subpixel SP3 may be a red subpixel, another one may be a green subpixel, and the remaining one may be a blue subpixel. The types of the plurality of subpixels are only illustrative, and the embodiments of the present specification are not limited thereto.

The plurality of pixels PX may each include one or more first subpixels SP1, one or more second subpixels SP2, and one or more third subpixels SP3. For example, a single pixel PX may include a pair of first subpixels SP1, a pair of second subpixels SP2, and a pair of third subpixels SP3. The pair of first subpixels SP1 may consist of a first-first subpixel SP1a and a first-second subpixel SP1b. The pair of second subpixels SP2 may consist of a second-first subpixel SP2a and a second-second subpixel SP2b. The pair of third subpixels SP3 may consist of a third-first subpixel SP3a and a third-second subpixel SP3b. For example, a single pixel PX may include the first-first subpixel SP1a, the first-second subpixel SP1b, the second-first subpixel SP2a, the second-second subpixel SP2b, the third-first subpixel SP3a, and the third-second subpixel SP3b, but the embodiments of the present specification are not limited thereto.

A plurality of subpixels constituting a single pixel PX may be arranged in various ways. For example, in a single pixel PX, the pair of first subpixels SP1 may be disposed in the same column, the pair of second subpixels SP2 may be disposed in the same column, and the pair of third subpixels SP3 may be disposed in the same column. The first subpixel SP1, the second subpixel SP2, and the third subpixel SP3 may be disposed in the same row. The number and arrangement of a plurality of subpixels constituting a single pixel PX are only illustrative, and the embodiments of the present specification are not limited thereto.

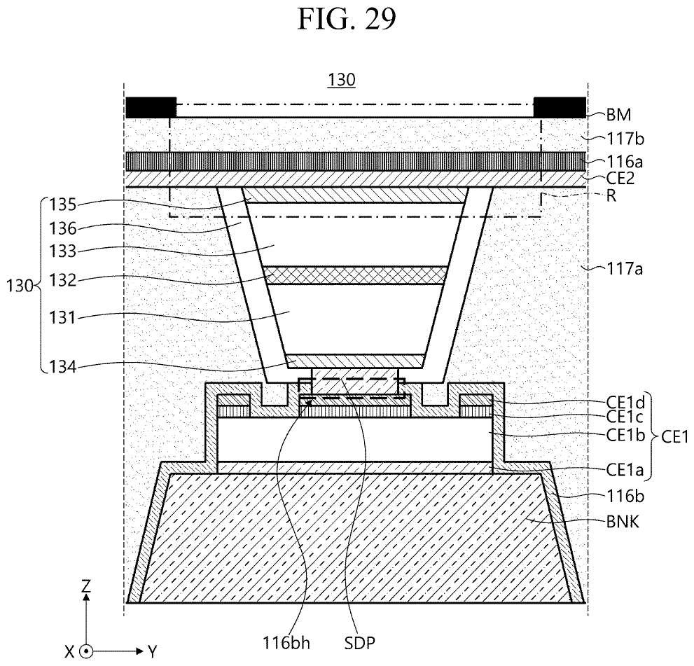

The plurality of signal lines TL may be disposed in an area between a plurality of subpixels. The plurality of signal lines TL may extend in a column direction between the plurality of subpixels. The plurality of signal lines TL may be lines that transmit an anode voltage from the pixel driving circuit PD to the plurality of subpixels. For example, the plurality of signal lines TL may be electrically connected to the plurality of pixel driving circuits PD and the first electrodes CE1 of the plurality of subpixels. The anode voltage output from the pixel driving circuit PD may be transmitted to the first electrodes CE1 of the plurality of subpixels through the plurality of signal lines TL. For example, the first electrode CE1 may be an electrode electrically connected to an anode electrode 134 (see FIG. 29) of the light emitting diode ED. Thus, the anode voltage from the signal line TL may be transmitted to the anode electrode 134 of the light emitting diode ED through the first electrode CEL.

Accordingly, instead of forming a plurality of transistors and a storage capacitor on each of the plurality of subpixels, the pixel driving circuit PD in which a plurality of pixel circuits are integrated may be used to simplify the structure of the display apparatus 1000. In addition, since circuits each disposed on one of the plurality of subpixels are integrated in a single pixel driving circuit PD, high efficiency low-power driving may be possible. The circuits each disposed on one of the plurality of subpixels SP and being integrated in a single pixel driving circuit PD may mean that the plurality of pixel circuits that can drive the plurality of light emitting diodes ED are included in the pixel driving circuit PD. The plurality of light emitting diodes ED may be driven by the single pixel driving circuit PD in which the plurality of pixel circuits are integrated. For example, a first-first light emitting diode 130a, a second-first light emitting diode 140a, and a third-first light emitting diode 150a may be driven by the single pixel driving circuit PD in which the plurality of pixel circuits are integrated. For example, the light emitting diode ED may be formed of a vertical type structure, but the embodiments of the present specification are not limited thereto.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may each be electrically connected to one of the pair of first subpixels SP1. The third signal line TL3 and the fourth signal line TL4 may each be electrically connected to one of the pair of second subpixels SP2. The fifth signal line TL5 and the sixth signal line TL6 may each be electrically connected to one of the pair of third subpixels SP3.

The first signal line TL1 may be disposed on one side of the pair of first subpixels SP1, and the second signal line TL2 may be disposed on the other side of the pair of first subpixels SPL. The first signal line TL1 may be electrically connected to the first electrode CE1 of one first subpixel SP1, e.g., the first-first subpixel SP1a, among the pair of first subpixels SP1. The second signal line TL2 may be electrically connected to the first electrode CE1 of the other first subpixel SP1, e.g., the first-second subpixel SP1b, among the pair of first subpixels SP1.

The third signal line TL3 may be disposed on one side of the pair of second subpixels SP2, and the fourth signal line TL4 may be disposed on the other side of the pair of second subpixels SP2. For example, the third signal line TL3 may be disposed to neighbor the second signal line TL2. The third signal line TL3 may be electrically connected to the first electrode CE1 of one second subpixel SP2, e.g., the second-first subpixel SP2a, among the pair of second subpixels SP2. The fourth signal line TL4 may be electrically connected to the first electrode CE1 of the other second subpixel SP2, e.g., the second-second subpixel SP2b, among the pair of second subpixels SP2.

The fifth signal line TL5 may be disposed on one side of the pair of third subpixels SP3, and the sixth signal line TL6 may be disposed on the other side of the pair of third subpixels SP3. For example, the fifth signal line TL5 may be disposed to neighbor the fourth signal line TL4. The sixth signal line TL6 may be disposed to neighbor the first signal line TL1 connected to a neighboring pixel PX. The fifth signal line TL5 may be electrically connected to the first electrode CE1 of one third subpixel SP3, e.g., the third-first subpixel SP3a, among the pair of third subpixels SP3. The sixth signal line TL6 may be electrically connected to the first electrode CE1 of the other third subpixel SP3, e.g., the third-second subpixel SP3b, among the pair of third subpixels SP3.

The plurality of signal lines TL may be made of a conductive material. For example, the plurality of signal lines TL may be made of a conductive material such as titanium (Ti), aluminum (Al), copper (Cu), molybdenum (Mo), nickel (Ni), chromium (Cr), indium tin oxide (ITO), indium zinc oxide (IZO), and indium gallium zinc oxide (IGZO), but the embodiments of the present specification are not limited thereto. In another example, the plurality of signal lines TL may be made of a multilayer structure of conductive materials. For example, the plurality of signal lines TL may be made of a multilayer structure of titanium (Ti)/aluminum (Al)/titanium (Ti)/indium tin oxide (ITO), but the embodiments of the present specification are not limited thereto.

The plurality of communication lines NL may be disposed in an area between the plurality of pixels PX. The plurality of communication lines NL may be disposed to extend in a row direction in the area between the plurality of pixels PX. The plurality of communication lines NL may be disposed in an area between the plurality of second electrodes CE2 and may not overlap the plurality of second electrodes CE2. For example, the plurality of communication lines NL may be lines used for short-range communication such as near field communication (NFC). The plurality of communication lines NL may serve as antennas. For example, the plurality of communication lines NL may be a plurality of connection lines or the like, but the embodiments of the present specification are not limited thereto.

According to the present specification, a bank BNK may be disposed on each of the plurality of subpixels. The plurality of banks BNK may be structures on which the plurality of light emitting diodes ED are seated. The plurality of banks BNK may guide positions of the plurality of light emitting diodes ED in a transfer process for transferring the plurality of light emitting diodes ED to the display apparatus 1000. The plurality of light emitting diodes ED may be transferred onto the plurality of banks BNK in the process of transferring the plurality of light emitting diodes ED. The plurality of banks BNK may be bank patterns or structures, but the embodiments of the present specification are not limited thereto.

The banks BNK of the first subpixels SP1, the banks BNK of the second subpixels SP2, and the banks BNK of the third subpixels SP3 may be disposed to be spaced from each other. The banks BNK of the first subpixels SP1, the banks BNK of the second subpixels SP2, and the banks BNK of the third subpixels SP3 may be configured to be separated. Thus, the banks BNK of the first subpixels SP1, the second subpixels SP2, and the third subpixels SP3 to which different types of light emitting diodes ED are transferred may be easily identified.

The bank BNK of the first-first subpixel SP1a and the bank BNK of the first-second subpixel SP1b may be connected to each other or may be formed to be spaced or separated from each other. For example, the bank BNK of the first-first subpixel SP1a and the bank BNK of the first-second subpixel SP1b on which the light emitting diodes ED of the same type are disposed in consideration of design, such as transfer process requirements or specifications, may be connected to each other or may be spaced or separated from each other. In addition, the bank BNK of the second-first subpixel SP2a and the bank BNK of the second-second subpixel SP2b may be connected to each other or may be formed to be spaced or separated from each other. The bank BNK of the third-first subpixel SP3a and the bank BNK of the third-second subpixel SP3b may be connected to each other or may be formed to be spaced or separated from each other. Therefore, the banks BNK of one pair of first subpixels SP1, the banks BNK of one pair of second subpixels SP2, and the banks BNK of one pair of third subpixels SP3 may be formed in various ways, but the embodiments of the present specification are not limited thereto.

For example, the plurality of banks BNK may be made of an organic insulating material. The plurality of banks BNK may be made of a single layer or multiple layers of an organic insulating material. For example, the plurality of banks BNK may be made of photoresist, polyimide (PI), or an acryl-based material, but the embodiments of the present specification are not limited thereto.

The first electrode CE1 may be disposed on each of the plurality of subpixels. The first electrode CE1 may be disposed on the bank BNK. The first electrode CE1 may be electrically connected to one signal line TL among the plurality of signal lines TL. At least one portion of the first electrode CE1 may extend to an outer side of the bank BNK and may be electrically connected to the signal line TL most adjacent to the first electrode CE1. For example, one portion of the first electrode CE1 of the first-first subpixel SP1a may extend to one side area of the first-first subpixel SP1a and may be electrically connected to the first signal line TL1, and one portion of the first electrode CE1 of the first-second subpixel SP1b may extend to the other side area of the first-second subpixel SP1b and may be electrically connected to the second signal line TL2. One portion of the first electrode CE1 of the second-first subpixel SP2a may extend to one side area of the second-first subpixel SP2a and may be electrically connected to the third signal line TL3, and one portion of the first electrode CE1 of the second-second subpixel SP2b may extend to the other side area of the second-second subpixel SP2b and may be electrically connected to the fourth signal line TL4. One portion of the first electrode CE1 of the third-first subpixel SP3a may extend to one side area of the third-first subpixel SP3a and may be electrically connected to the fifth signal line TL5, and one portion of the first electrode CE1 of the third-second subpixel SP3b may extend to the other side area of the third-second subpixel SP3b and may be electrically connected to the sixth signal line TL6.

The first electrode CE1 may be electrically connected to the anode electrode 134 of the light emitting diode ED and may transmit the anode voltage from the pixel driving circuit PD to the light emitting diode ED through the signal line TL. Different voltages may be applied to the first electrode CE1 of each of the plurality of subpixels according to an image being displayed. For example, voltages different from each other may be applied to the first electrode CE1 of each of the plurality of subpixels. Thus, the first electrode CE1 may be a pixel electrode, but the embodiments of the present specification are not limited thereto.

The first electrode CE1 may be made of a conductive material. For example, the first electrode CE1 may be integrally configured with the plurality of signal lines TL. For example, the first electrode CE1 may be made of the same conductive material as the plurality of signal lines TL, but the embodiments of the present specification are not limited thereto. For example, the first electrode CE1 may be made of a conductive material such as titanium (Ti), aluminum (Al), copper (Cu), molybdenum (Mo), nickel (Ni), chromium (Cr), indium tin oxide (ITO), indium zinc oxide (IZO), and indium gallium zinc oxide (IGZO), but the embodiments of the present specification are not limited thereto. In another example, the first electrode CE1 may be made of a multilayer structure of conductive materials. For example, the plurality of first electrodes CE1 may be made of a multilayer structure of titanium (Ti)/aluminum (Al)/titanium (Ti)/indium tin oxide (ITO), but the embodiments of the present specification are not limited thereto.

The light emitting diode ED may be disposed on each of the plurality of subpixels. The plurality of light emitting diodes ED may be any one of inorganic light-emitting diodes (LEDs) and micro light-emitting diodes (micro LEDs), but the embodiments of the present specification are not limited thereto. The plurality of light emitting diodes ED may be disposed on the bank BNK and the first electrode CE1. The plurality of light emitting diodes ED may be disposed on the first electrode CE1 and may be electrically connected to the first electrode CE1. Therefore, the light emitting diode ED may emit light by receiving the anode voltage from the pixel driving circuit PD through the signal line TL and the first electrode CE1.

The plurality of light emitting diodes ED may include a first light emitting diode 130, a second light emitting diode 140, and a third light emitting diode 150. The first light emitting diode 130 may be disposed on the first subpixel SP1. The second light emitting diode 140 may be disposed on the second subpixel SP2. The third light emitting diode 150 may be disposed on the third subpixel SP3. For example, any one of the first light emitting diode 130, the second light emitting diode 140, and the third light emitting diode 150 may be a red light emitting diode, another one may be a green light emitting diode, and the remaining one may be a blue light emitting diode. The embodiments of the present specification are not limited thereto. Thus, red light, green light, and blue light emitted from the plurality of light emitting diodes ED may be combined to implement lights of various colors including white light. The types of the plurality of light emitting diodes ED are only illustrative, and the embodiments of the present specification are not limited thereto.

The first light emitting diode 130 may include the first-first light emitting diode 130a disposed on the first-first subpixel SP1a and a first-second light emitting diode 130b disposed on the first-second subpixel SP1b. The second light emitting diode 140 may include the second-first light emitting diode 140a disposed on the second-first subpixel SP2a and a second-second light emitting diode 140b disposed on the second-second subpixel SP2b. The third light emitting diode 150 may include the third-first light emitting diode 150a disposed on the third-first subpixel SP3a and a third-second light emitting diode 150b disposed on the third-second subpixel SP3b.

As shown in FIGS. 4 to 6, the second electrode CE2 may be disposed on each of the plurality of subpixels. The second electrode CE2 may be disposed on the light emitting diode ED. The second electrode CE2 may be electrically connected to the pixel driving circuit PD through a plurality of contact electrodes CCE.

For example, the second electrode CE2 may be electrically connected to a cathode electrode 135 (see FIG. 29) of the light emitting diode ED and may transmit a cathode voltage from the pixel driving circuit PD to the light emitting diode ED. The same cathode voltage may be applied to the second electrode CE2 of each of the plurality of subpixels. For example, the same voltage may be applied to the second electrode CE2 of each of the plurality of subpixels and the cathode electrode 135 of the light emitting diode ED. Thus, the second electrode CE2 may be a common electrode, but the embodiments of the present specification are not limited thereto.

At least some of the plurality of subpixels may share the second electrode CE2. At least some of the second electrodes CE2 of the plurality of subpixels may be electrically connected to each other. As the same voltage is applied to the second electrodes CE2, the second electrodes CE2 of at least some of the subpixels may be shared and used. For example, the second electrodes CE2 of at least some pixels PX among the plurality of pixels PX disposed in the same row may be connected to each other. For example, a single second electrode CE2 may be disposed on the plurality of pixels PX. A single second electrode CE2 may be disposed for every n subpixels.

For example, some of the second electrodes CE2 of the plurality of subpixels may be disposed to be spaced or separated from each other. For example, the second electrode CE2 connected to pixels PX of an n^{th} row and the second electrode CE2 connected to pixels PX of an (n+1)^{th} row may be disposed to be spaced or separated from each other. For example, the plurality of second electrodes CE2 may be disposed to be spaced from each other with the plurality of communication lines NL, which extend in the row direction, disposed therebetween. Thus, the number of the plurality of subpixels may be greater than the number of the plurality of second electrodes CE2. In another example, all of the second electrodes CE2 of the plurality of subpixels may be connected to each other and only one second electrode CE2 may be disposed on the substrate 110, but the embodiments of the present specification are not limited thereto.

The plurality of second electrodes CE2 may be made of a transparent conductive material, but the embodiments of the present specification are not limited thereto. The plurality of second electrodes CE2 may be made of a transparent conductive material so that light emitted from the light emitting diode ED is directed toward an upper portion of the second electrode CE2. For example, the second electrode CE2 may be made of a transparent conductive material such as indium tin oxide (ITO), indium zinc oxide (IZO), and indium gallium zinc oxide (IGZO), but the embodiments of the present specification are not limited thereto.

The plurality of contact electrodes CCE may be disposed on the substrate 110. For example, the plurality of contact electrodes CCE may be disposed to be spaced from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 and may transmit a cathode voltage from the pixel driving circuit PD to the second electrode CE2.

For example, in a case in which a micro LED is used as the light emitting diode ED, a plurality of micro LEDs may be formed on a wafer, and the micro LEDs may be transferred to the substrate 110 of the display apparatus 1000 to manufacture the display apparatus 1000. Various defects may occur in a process of transferring the plurality of light emitting diodes ED having a fine size from the wafer to the substrate 110. For example, a non-transfer defect in which the light emitting diode ED is not transferred may occur in some subpixels, and a defect in which the light emitting diode ED is transferred while deviating from its correct position due to an alignment error may occur in some other subpixels. In addition, even when the transfer process is normally performed, the transferred light emitting diode ED itself may be defective. Therefore, during the process of transferring the plurality of light emitting diodes ED, in consideration of the defects, a plurality of light emitting diodes ED of the same type may be transferred to a single subpixel. A lighting test of the plurality of light emitting diodes ED may be performed, and only one light emitting diode ED that is judged normal may be finally used.

For example, the first-first light emitting diode 130a and the first-second light emitting diode 130b may be transferred together to a single pixel PX, and whether there are defects may be tested. If both the first-first light emitting diode 130a and the first-second light emitting diode 130b are judged normal, only the first-first light emitting diode 130a may be used, and the first-second light emitting diode 130b may not be used. In another example, if only the first-second light emitting diode 130b is judged normal among the first-first light emitting diode 130a and the first-second light emitting diode 130b, the first-first light emitting diode 130a may not be used, and only the first-second light emitting diode 130b may be used. Therefore, even when a plurality of light emitting diodes ED of the same type are transferred to a single pixel PX, only one light emitting diode ED may be finally used.

Thus, any one of the pair of light emitting diodes ED may be a main or primary light emitting diode ED, and the other may be a redundancy light emitting diode ED. The redundancy light emitting diode ED may be an extra light emitting diode ED transferred in preparation for a defect of the main light emitting diode ED. When a defect occurs in the main light emitting diode ED, the redundancy light emitting diode ED may be used instead. Therefore, by transferring the main light emitting diode ED and the redundancy light emitting diode ED together to a single pixel PX, a decrease in display quality due to defects of the main light emitting diode ED and the redundancy light emitting diode ED can be minimized or reduced.

For example, the first-first light emitting diode 130a, the second-first light emitting diode 140a, and the third-first light emitting diode 150a transferred to a single pixel PX may be used as main light emitting diodes ED, and the first-second light emitting diode 130b, the second-second light emitting diode 140b, and the third-second light emitting diode 150b may be used as redundancy light emitting diodes ED.

FIGS. 7 to 17 are plan views illustrating the display apparatus according to an example embodiment of the present specification.

FIGS. 7 to 12 are partially enlarged views (B1, B2, B3, B4, B5, and B6) showing portion B of FIG. 3 in an enlarged manner. FIGS. 7 to 12 each illustrate a display apparatus according to one of first to sixth embodiments. Components of different embodiments that perform substantially the same function will be denoted by the same reference numerals, and detailed description thereof will be omitted.

As shown in FIGS. 7 to 12, a display apparatus according to a first example embodiment may include a display area AA and a first non-display area NA1. The display area AA may include a plurality of light emitting diodes 130, 140, and 150, a second electrode CE2, a first optical layer 117a, a second optical layer 117b, and a third optical layer 117c. The first non-display area NA1 may include a plurality of light emitting diodes 130, 140, and 150, a first optical layer 117a, a second optical layer 117b, and a third optical layer 117c.

The plurality of light emitting diodes 130, 140, and 150 disposed in the display area AA may emit light due to a high-potential power voltage applied to a first electrode as a plurality of second electrodes CE2 are disposed. The second electrode CE2 may be formed to entirely cover a plurality of pixels to be common to the plurality of pixels. The second electrode CE2 may be formed to be common only to the plurality of light emitting diodes 130, 140, and 150 disposed on each pixel. However, the present specification is not limited thereto.

The plurality of light emitting diodes 130, 140, and 150 disposed in the display area AA and the first non-display area NA1 may include a first light emitting diode 130, a second light emitting diode 140, and a third light emitting diode 150. The first light emitting diode 130, the second light emitting diode 140, and the third light emitting diode 150 may implement a first color, a second color, and a third color, respectively. The first to third colors may be different colors. For example, the first to third colors may be any one of red, green, and blue and not overlap one another, but the embodiments of the present specification are not limited thereto. For example, the first color may be red, the second color may be green, and the third color may be blue, but the present specification is not limited thereto.

The first light emitting diode 130 may have a first size, the second light emitting diode 140 may have a second size, and the third light emitting diode 150 may have a third size. The first size may be different from the second size and/or the third size. The first size may be larger than the second size and/or the third size. By designing the first size of the first light emitting diode 130 implementing the first color to be different from the second size of the second light emitting diode 140 and/or the third size of the third light emitting diode 150, the light efficiency of the display apparatus 1000 can be improved.

The first non-display area NA1 may include a dummy area DUA. The dummy area DUA may include a dummy pixel including a plurality of dummy light emitting diodes. The second electrode CE2 may not be disposed in the first non-display area NA1 in which the plurality of dummy light emitting diodes are disposed. Therefore, even when a high-potential power voltage is applied to the first electrode disposed on the dummy light emitting diode, the dummy light emitting diode may not be able to emit light.

As shown also in FIG. 3, the first non-display area NA1 may include an area in which a trench T is disposed. The trench T may be disposed between the plurality of dummy light emitting diodes. The area in which the trench T is disposed may be formed to have a shape that is substantially the same as the shape of the first non-display area NA1. For example, the first non-display area NA1 may have a rectangular shape with four round corners. In this case, the area in which the trench T is disposed may have a rectangular shape with four round corners. An area of the rectangular shape formed due to an outermost periphery of the area in which the trench T is disposed may be smaller than an area of the rectangular shape formed due to an outermost periphery of the first non-display area NA1. The area in which the trench T is formed may be disposed to surround a plurality of pixels PX.

In one embodiment, the display area AA may include an area in which a trench T is formed. The area in which the trench T is formed may be disposed to surround a plurality of pixels PX.

The trench T may be disposed to surround the plurality of pixels PX. At least one portion of the trench T may be disposed between the plurality of light emitting diodes 130, 140, and 150. The plurality of light emitting diodes 130, 140, and 150 may be disposed in the display area AA and/or the first non-display area NA1. The trench T may be disposed between the display area AA and the bending area BA. The trench T may be disposed between the display panel 100 and the bending area BA. The trench T may be disposed between at least one portion of the display panel 100 and the bending area BA. The trench T may be disposed around the display area AA and in the first non-display area NA1.

As shown in FIG. 7, a first trench T1 may be disposed between the plurality of light emitting diodes 130, 140, and 150. The first trench T1 may be disposed to extend in a first direction (for example, the X-axis direction). The first trench T1 may be disposed between the first light emitting diode 130 and the second light emitting diode 140, but the present specification is not limited thereto. Since the first trench T1 is disposed, the display panel 100 may be protected from permeation of moisture from the outside. For example, since effects such as prevention or suppression of moisture permeation can be implemented, the reliability of the display apparatus 1000 can be improved.

A single pixel may include the first light emitting diode 130, the second light emitting diode 140, and the third light emitting diode 150. The third optical layer 117c may be disposed between a plurality of pixels disposed in the first direction (for example, the X-axis direction). For example, the third optical layer 117c may be disposed to extend in a second direction (for example, the Y-axis direction) intersecting the first direction.

The first optical layer 117a and the second optical layer 117b may be disposed to overlap each other in a planar direction (for example, the Z-axis direction) of an area in which a pixel or a dummy pixel is disposed and the display panel 100. The third optical layer 117c may be disposed between a plurality of first optical layers 117a and a plurality of second optical layers 117b (for example, in the X-axis direction).

In one embodiment, the first optical layer 117a may extend to one end (or one side) of the display panel. The second optical layer 117b may be disposed in the display area AA. The second optical layer 117b may be disposed on the first optical layer 117a. Therefore, thicknesses of the optical layers 117a and 117b of the display panel 100 may gradually decrease in the second direction (for example, the Y-axis direction). An end (or one side) of the second electrode CE2 in the first direction and an end (or one side) of the second optical layer 117b in the first direction may be formed to meet at substantially the same point. The display area AA may include the second electrode CE2 and the second optical layer 117b.

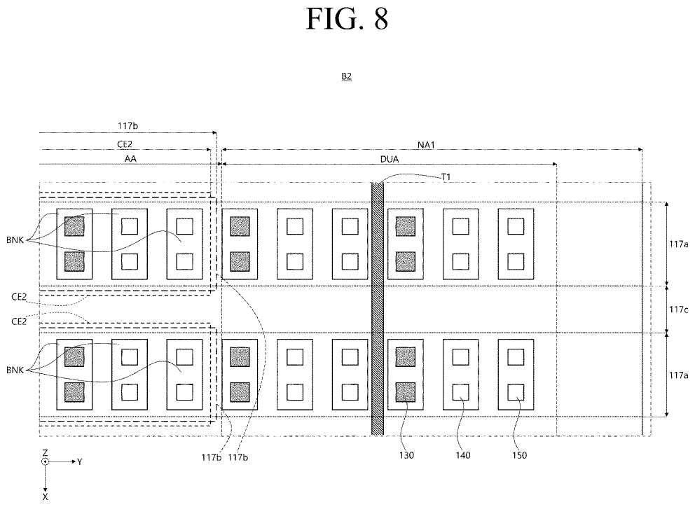

As shown in FIG. 8, a first trench T1 may be disposed between a plurality of light emitting diodes 130, 140, and 150 in a display apparatus according to a second example embodiment. The first trench T1 may be disposed to extend in the first direction (for example, the X-axis direction). The first trench T1 may be disposed between the third light emitting diode 150 and the first light emitting diode 130, but the present specification is not limited thereto. Since the first trench T1 is disposed, the display panel 100 may be protected from permeation of moisture from the outside. For example, since effects such as prevention or suppression of moisture permeation can be implemented, the reliability of the display apparatus 1000 can be improved.

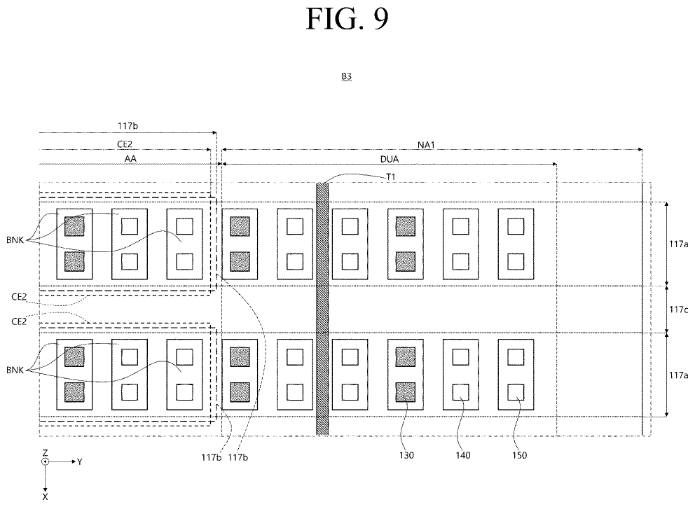

As shown in FIG. 9, a first trench T1 may be disposed between a plurality of light emitting diodes 130, 140, and 150 in a display apparatus according to a third example embodiment. The first trench T1 may be disposed to extend in the first direction (for example, the X-axis direction. The first trench T1 may be disposed between the second light emitting diode 140 and the third light emitting diode 150, but the present specification is not limited thereto. Since the trench is disposed between the second light emitting diode 140 and the third light emitting diode 150 having a relatively small size, a design margin of the display panel can be secured. Therefore, the probability of defective transfer of a light emitting diode can be reduced in a process of manufacturing the display panel. Thus, the productivity of the display apparatus can be improved.

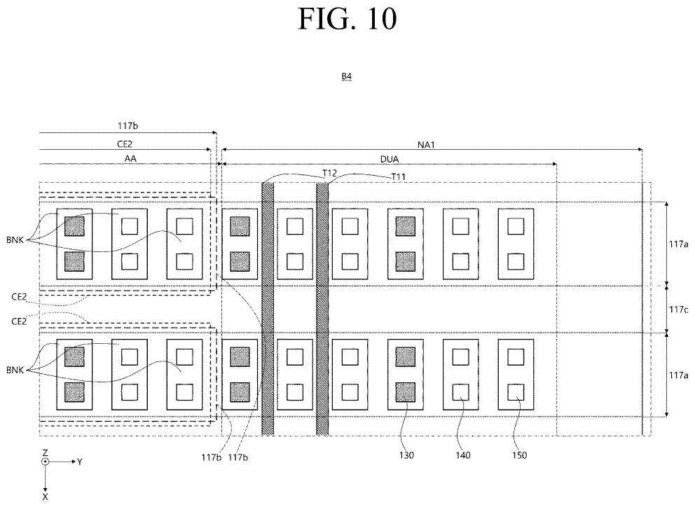

As shown in FIG. 10, an eleventh trench T11 and/or a twelfth trench T12 may be disposed between a plurality of light emitting diodes 130, 140, and 150 in a display apparatus according to a fourth example embodiment. The eleventh trench T11 and/or the twelfth trench T12 may be disposed to extend in the first direction (for example, the X-axis direction). The eleventh trench T11 may be disposed between the second light emitting diode 140 and the third light emitting diode 150, and the twelfth trench T12 may be disposed between the first light emitting diode 130 and the second light emitting diode 140, but the present specification is not limited thereto. Since the trench is disposed between the second light emitting diode 140 and the third light emitting diode 150 having a relatively small size, a design margin of the display panel can be secured. In addition, since a plurality of trenches are disposed, effects such as prevention or suppression of moisture permeation can be further enhanced.

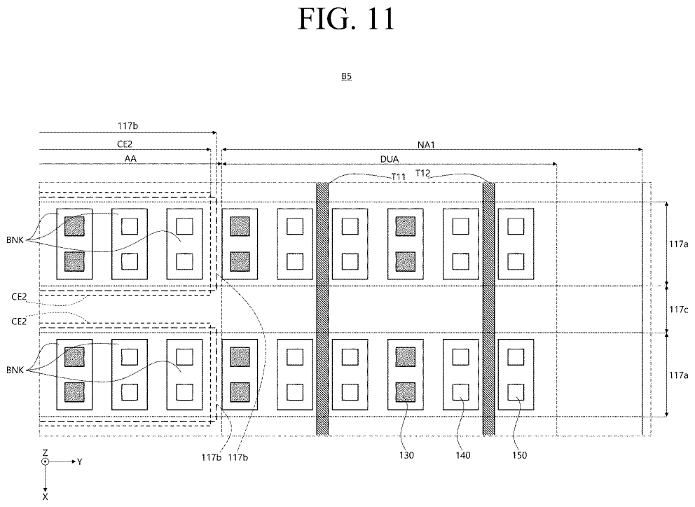

As shown in FIG. 11, an eleventh trench T11 and/or a twelfth trench T12 may be disposed between a plurality of light emitting diodes 130, 140, and 150 in a display apparatus according to a fifth example embodiment. The eleventh trench T11 and/or the twelfth trench T12 may be disposed to extend in the first direction (for example, the X-axis direction). The eleventh trench T11 may be disposed between the second light emitting diode 140 and the third light emitting diode 150, and the twelfth trench T12 may be disposed between another second light emitting diode 140 and another third light emitting diode 150, but the present specification is not limited thereto. Since the trench is disposed between the second light emitting diode 140 and the third light emitting diode 150 having a relatively small size, a design margin of the display panel can be secured. In addition, since a plurality of trenches are disposed, effects such as prevention or suppression of moisture permeation can be further enhanced.

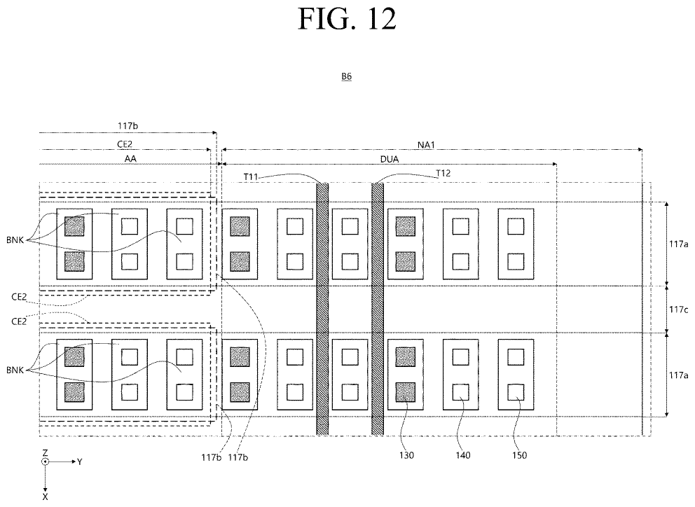

As shown in FIG. 12, an eleventh trench T11 and/or a twelfth trench T12 may be disposed between a plurality of light emitting diodes 130, 140, and 150 in a display apparatus according to a sixth example embodiment. The eleventh trench T11 and/or the twelfth trench T12 may be disposed to extend in the first direction (for example, the X-axis direction). The eleventh trench T11 may be disposed between the second light emitting diode 140 and the third light emitting diode 150, and the twelfth trench T12 may be disposed between the third light emitting diode 150 and the first light emitting diode 130, but the present specification is not limited thereto. Since the trench is disposed between the second light emitting diode 140 and the third light emitting diode 150 having a relatively small size, a design margin of the display panel can be secured. In addition, since a plurality of trenches are disposed, effects such as prevention or suppression of moisture permeation can be further enhanced.

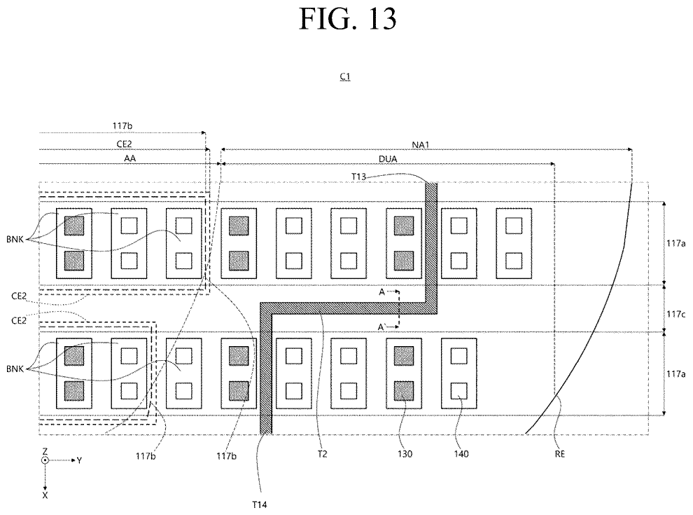

FIGS. 13 to 16 are partially enlarged views (C1, C2, C3, and C4) showing portion C of FIG. 3 in an enlarged manner. FIGS. 13 to 16 each illustrate a display apparatus according to one of seventh to tenth example embodiments. Substantially the same components as the above-described embodiments or between different embodiments will be denoted by the same reference numerals, and detailed description thereof may be omitted.

As shown in FIG. 13, a display apparatus may include a round edge RE, but the embodiments of the present specification are not limited thereto. The round edge RE may include a thirteenth trench T13, a fourteenth trench T14, and a second trench T2. The thirteenth trench T13 and the fourteenth trench T14 may be disposed to extend in the first direction. The second trench T2 may be disposed to extend in the second direction intersecting the first direction. As illustrated, the first direction and the second direction intersect at angles perpendicular to each other in the X-axis direction and the Y-axis direction, but directions in which the thirteenth trench T13, the fourteenth trench T14, and the second trench T2 are disposed to extend are not limited thereto. For example, an arrangement angle of a trench may be set or adjusted.

A display apparatus according to a seventh embodiment may include a display area AA and a first non-display area NA1.

The plurality of light emitting diodes 130, 140, and 150 disposed in the display area AA may emit light due to a high-potential power voltage applied to a first electrode as a plurality of second electrodes CE2 are disposed. The second electrode CE2 may be formed to correspond to the shape of the display area AA due to the round edge RE. For example, an area covering the plurality of light emitting diodes 130, 140, and 150 may gradually decrease in the first direction (for example, the X-axis direction).

The first non-display area NA1 may include a dummy area DUA. The dummy area DUA may also be formed to correspond to the shape of the first non-display area NA1 due to the round edge RE. For example, an area covering a plurality of dummy light emitting diodes may gradually decrease in the first direction (for example, the X-axis direction).

The thirteenth trench T13, the fourteenth trench T14, and the second trench T2 may be disposed between the plurality of light emitting diodes 130, 140, and 150. The thirteenth trench T13 may be disposed between the first light emitting diode 130 and the second light emitting diode 140. The fourteenth trench T14 may be disposed on a dummy pixel disposed in the first direction (for example, the X-axis direction) from a dummy pixel including the first light emitting diode 130 and the second light emitting diode 140 between which the thirteenth trench T13 is disposed. The fourteenth trench T14 may be disposed between another first light emitting diode 130 and another second light emitting diode 140. The second trench T2 may be disposed between a plurality of pixels. The second trench T2 may be disposed to extend in the second direction (for example, the Y-axis direction) intersecting the first direction between dummy pixels disposed in the first direction (for example, the X-axis direction). The second trench T2 may be disposed between the plurality of light emitting diodes 130, 140, and 150. The second trench T2 may be disposed between second light emitting diodes 140 each implementing the same color, between third light emitting diodes 150, or between first light emitting diodes 130. Accordingly, an edge of the display panel can be protected. For example, effects such as prevention or suppression of moisture permeation can be implemented. Therefore, the reliability of the display apparatus can be improved. Although the round edge RE has been described above, the embodiments of the present specification are not limited thereto. In a case in which an edge has another shape, a trench disposed to correspond to the edge may be configured by changing the embodiments described above.

The first optical layer 117a, the second optical layer 117b, and the third optical layer 117c may be formed to correspond to the shape of the first non-display area NA1 due to the round edge RE. For example, the size of an area in which the first optical layer 117a, the second optical layer 117b, and the third optical layer 117c overlap the display panel may gradually decrease in the first direction. The second optical layer 117b may be disposed in the display area AA. An end (or one side) of the second electrode CE2 in the first direction and an end (or one side) of the second optical layer 117b in the first direction may be formed to meet at substantially the same point. The display area AA may include the second electrode CE2 and the second optical layer 117b.

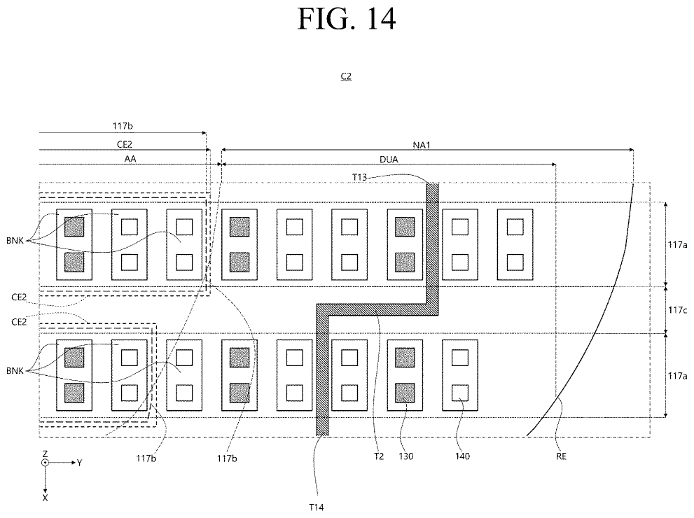

As shown in FIG. 14, the thirteenth trench T13, the fourteenth trench T14, and the second trench T2 may be disposed between the plurality of light emitting diodes 130, 140, and 150 in a display apparatus according to an eighth example embodiment. The thirteenth trench T13 may be disposed between the first light emitting diode 130 and the second light emitting diode 140. The fourteenth trench T14 may be disposed between another second light emitting diode 140 and the third light emitting diode 150. The second trench T2 may be disposed between a plurality of pixels. The second trench T2 may be disposed between second light emitting diodes 140 each implementing the same color or between first light emitting diodes 130.

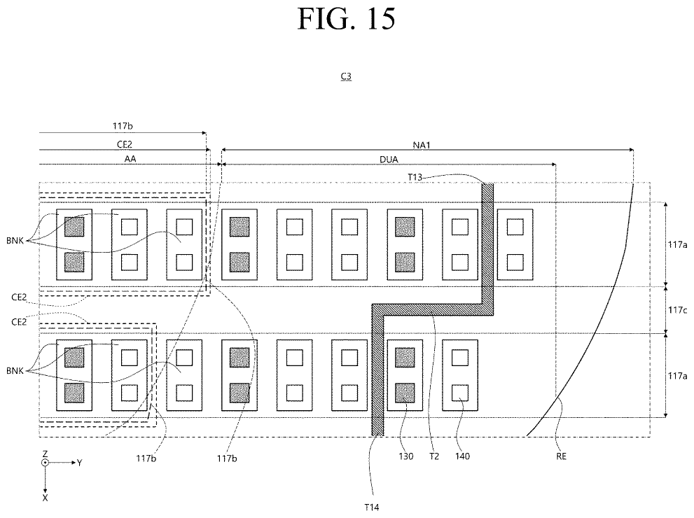

As shown in FIG. 15, the thirteenth trench T13, the fourteenth trench T14, and the second trench T2 may be disposed between the plurality of light emitting diodes 130, 140, and 150 in a display apparatus according to a ninth example embodiment. The thirteenth trench T13 may be disposed between the second light emitting diode 140 and the third light emitting diode 150. The fourteenth trench T14 may be disposed between another third light emitting diode 150 and the first light emitting diode 130. The second trench T2 may be disposed between a plurality of pixels. The second trench T2 may be disposed between first light emitting diodes 130 each implementing the same color or between second light emitting diodes 140.

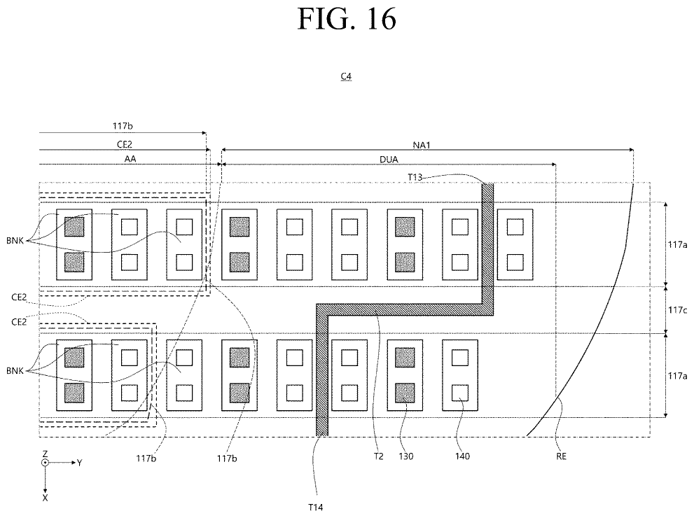

As shown in FIG. 16, according to a tenth example embodiment, the thirteenth trench T13, the fourteenth trench T14, and the second trench T2 may be disposed between the plurality of light emitting diodes 130, 140, and 150. The thirteenth trench T13 may be disposed between the second light emitting diode 140 and the third light emitting diode 150. The fourteenth trench T14 may be disposed between another second light emitting diode 140 and another third light emitting diode 150. The second trench T2 may be disposed between a plurality of pixels. The second trench T2 may be disposed between third light emitting diodes 150 each implementing the same color, between first light emitting diodes 130, or between second light emitting diodes 140.

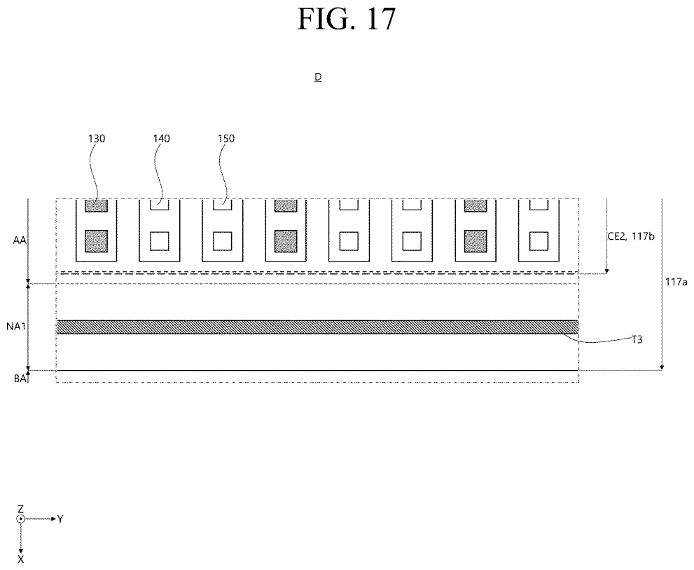

FIG. 17 is a partially enlarged view showing portion D of FIG. 3 in an enlarged manner. FIG. 17 illustrates a display apparatus according to an eleventh example embodiment.

As shown in FIG. 17, the display apparatus according to the eleventh embodiment may include a display area AA and a first non-display area NA1. The display area AA may include the second electrode CE2 and the second optical layer 117b. Ends of the second electrode CE2 and the second optical layer 117b in the first direction may be formed to meet at substantially the same point.

The first non-display area NA1 may be disposed between the bending area BA and the display area AA. The bending area BA may be disposed in a first direction from the display panel 100. The first non-display area NA1 may include a third trench T3. The third trench T3 may be disposed to extend in the second direction intersecting the first direction. The third trench T3 may be disposed between the bending area BA and the display area AA or the display panel 100. When the bending area BA is bent, an end of the first non-display area NA1 in the first direction may form one side of the display apparatus. The third trench T3 may block moisture or the like penetrating in a direction in which the bending area BA is disposed. Accordingly, the reliability of the display apparatus may be improved, and the service life of the display apparatus may increase.

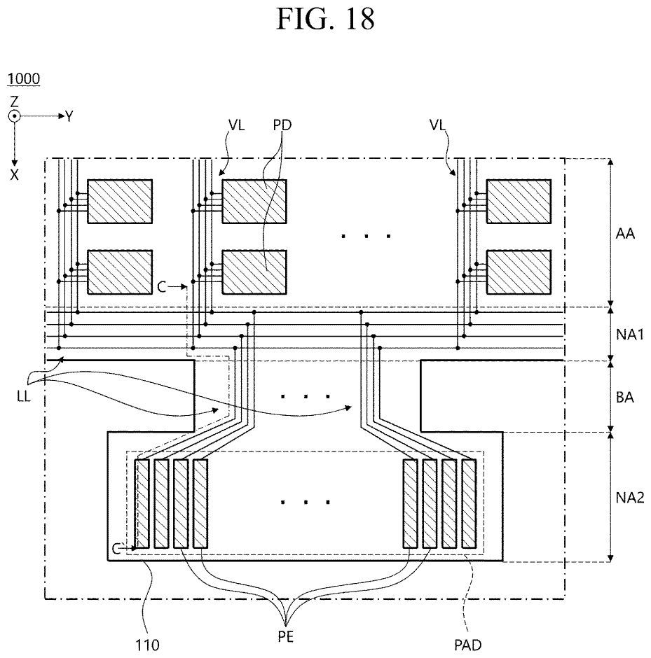

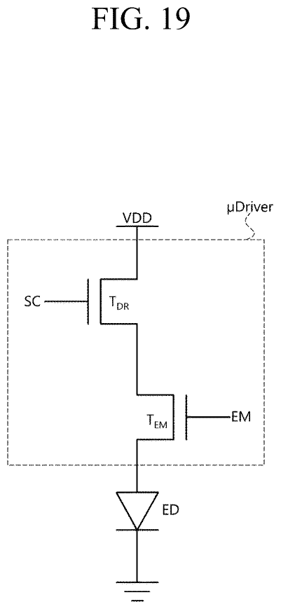

FIG. 19 is a view illustrating a circuit structure according to an example embodiment of the present specification.

Although FIG. 19 shows that a single light emitting diode ED is connected to a micro driver μDriver, the present specification is not limited thereto. For example, eight light emitting diodes ED may be connected to a single micro driver μDriver. In another example, sixteen light emitting diodes ED may be connected to a single micro driver μDriver, or thirty-two light emitting diodes ED or sixty-four light emitting diodes ED may be simultaneously connected to a single micro driver μDriver. The light emitting diodes ED may be micro light emitting diodes (μ-LEDs).

A single micro driver μDriver may include a driving transistor T_{DR} and a light emitting transistor T_{EM}, but the embodiments of the present specification are not limited thereto.

For example, the driving transistor T_{DR} may have a first electrode to which a high-potential power voltage VDD is applied, a second electrode connected to a first electrode of the light emitting transistor T_{EM}, and a gate electrode to which a scan signal SC is applied. The scan signal SC applied to the gate electrode of the driving transistor T_{DR} may be direct current power, and a fixed reference voltage (Vref) may be applied every frame, but the embodiments of the present specification are not limited thereto.

The light emitting transistor T_{EM} may have the first electrode to which the second electrode of the driving transistor T_{DR} is connected, a second electrode to which the light emitting diode ED is connected, and a gate electrode to which a light emitting signal EM is applied. The light emitting signal EM applied to the gate electrode of the light emitting transistor T_{EM} may be a pulse width modulation signal that changes every frame, but the embodiments of the present specification are not limited thereto.

A first electrode of the light emitting diode ED may be connected to the second electrode of the light emitting transistor T_{EM}, and a second electrode of the light emitting diode ED may be connected to a ground. For example, the first electrode of the light emitting diode ED may be an anode electrode, and the second electrode of the light emitting diode ED may be a cathode electrode, but the embodiments of the present specification are not limited thereto.

The driving transistor T_{DR} and the light emitting transistor T_{EM} may each be an n-type transistor or a p-type transistor.

In the micro driver μDriver, the driving transistor T_{DR} may be turned on due to the scan signal SC applied from a timing controller (T-CON), and the light emitting transistor T_{EM} may be turned on due to the light emitting signal EM. By this, the light emitting diode ED may emit light as driving current is applied to the light emitting diode ED via the driving transistor T_{DR} and the light emitting transistor T_{EM} due to the high-potential power voltage VDD applied to the first electrode of the driving transistor T_{DR}.

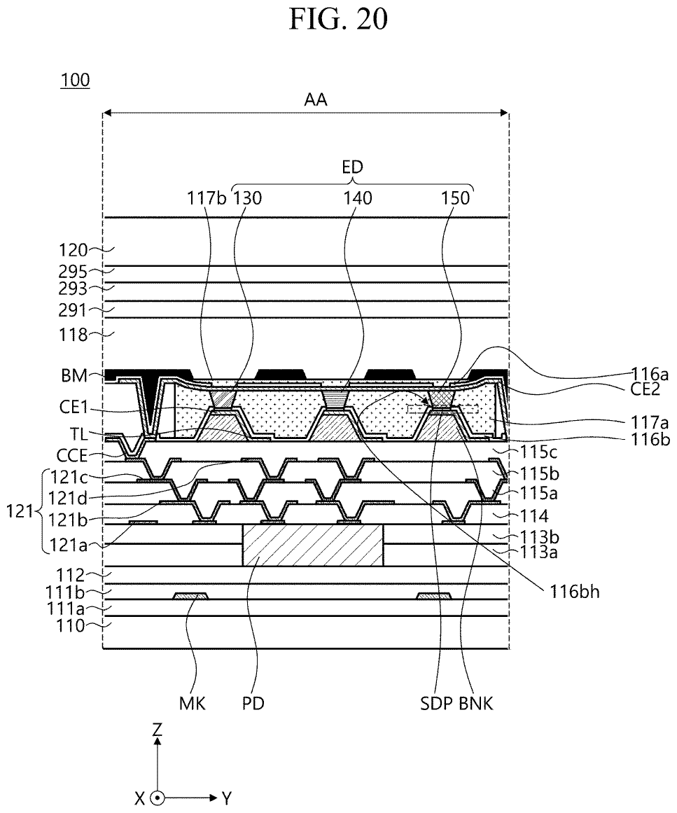

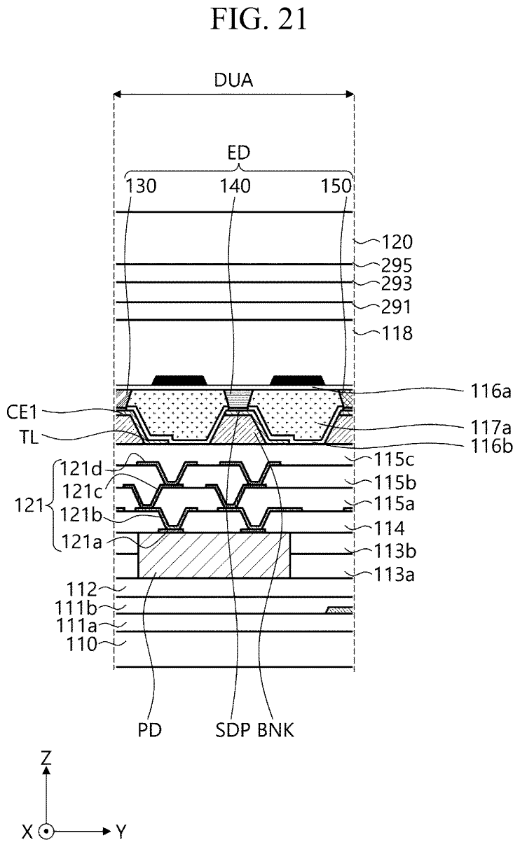

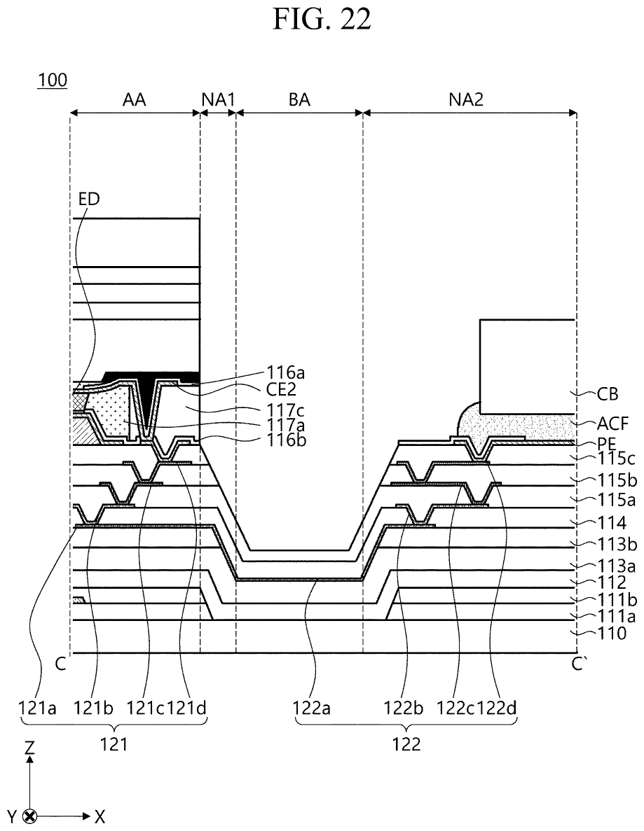

FIGS. 20 and 22 are cross-sectional views illustrating the display apparatus according to an example embodiment of the present specification. FIG. 21 is a cross-sectional view illustrating the display apparatus according to an example embodiment of the present specification.

FIGS. 20 and 22 are cross-sectional views of the display area AA, the first non-display area NA1, the bending area BA, and the second non-display area NA2. FIG. 22 is a cross-sectional view along line C-C′ in FIG. 18.

FIG. 21 is a cross-sectional view of the dummy area DUA. Substantially the same components in different cross-sectional views will be denoted by the same reference numerals, and detailed description thereof will be omitted.

As shown in FIGS. 20, 21, and 22, a first buffer layer 111a and a second buffer layer 111b may be disposed in the remaining area of the substrate 110 excluding the bending area BA.

The first buffer layer 111a and the second buffer layer 111b may be disposed in the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be made of an inorganic insulating material. For example, the first buffer layer 111a and the second buffer layer 111b may be made of a single layer or multiple layers of silicon oxide (SiOx) or silicon nitride (SiNx), but the embodiments of the present specification are not limited thereto.

For example, portions of the first buffer layer 111a and the second buffer layer 111b present in the bending area BA may be removed. An upper surface of the substrate 110 located in the bending area BA may be exposed from the first buffer layer 111a and the second buffer layer 111b. By removing the first buffer layer 111a and the second buffer layer 111b made of an inorganic insulating material from the bending area BA, it is possible to minimize or reduce cracks in the first buffer layer 111a and the second buffer layer 111b that may occur at the time of bending.

A plurality of align keys MK may be disposed between the first buffer layer 111a and the second buffer layer 111b. The plurality of align keys MK may be configured to identify the position of the pixel driving circuit PD during the process of manufacturing the display apparatus 1000. For example, the plurality of align keys MK may be configured to align the position of the pixel driving circuit PD transferred onto an adhesive layer 112. In another example, the plurality of align keys MK may be omitted.

The adhesive layer 112 may be disposed on the second buffer layer 111b. The adhesive layer 112 may be disposed in the display area AA, the first non-display area NA1, the bending area BA, and the second non-display area NA2. In another example, at least one portion of the adhesive layer 112 may be removed from the non-display area NA including the bending area BA. For example, the adhesive layer 112 may be made of any one of an adhesive polymer, an epoxy resin, a UV curable resin, a polyimide-based material, an acrylate-based material, a urethane-based material, and polydimethylsiloxane (PDMS), but the embodiments of the present specification are not limited thereto.

In the display area AA, the pixel driving circuit PD may be disposed on the adhesive layer 112. When the pixel driving circuit PD is implemented as a driving driver, the driving driver may be mounted on the adhesive layer 112 by a transfer process, but the embodiments of the present specification are not limited thereto.

A first protective layer 113a and a second protective layer 113b may be disposed on the adhesive layer 112 and the pixel driving circuit PD. The first protective layer 113a and the second protective layer 113b may be disposed to surround a side surface of the pixel driving circuit PD, but the embodiments of the present specification are not limited thereto. For example, the second protective layer 113b may be disposed to cover at least one portion of an upper surface of the pixel driving circuit PD. For example, at least one of the first protective layer 113a and the second protective layer 113b disposed in the bending area BA may be omitted. For example, the first protective layer 113a may be entirely disposed in the display area AA and the non-display area NA, and the second protective layer 113b may be partially disposed in the display area AA, the first non-display area NA1, and the second non-display area NA2. For example, one portion of the second protective layer 113b present in the bending area BA may be removed. However, the embodiments of the present specification are not limited thereto.

The first protective layer 113a and the second protective layer 113b may be made of an organic insulating material, but the embodiments of the present specification are not limited thereto. For example, the first protective layer 113a and the second protective layer 113b may be made of photoresist, polyimide (PI), or a photo acryl-based material, but the embodiments of the present specification are not limited thereto. For example, the first protective layer 113a and the second protective layer 113b may be overcoating layers or insulating layers, but the embodiments of the present specification are not limited thereto.

According to the present specification, a plurality of first connection lines 121 may be disposed on the second protective layer 113b in the display area AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a first-first connection line 121a, a first-second connection line 121b, a first-third connection line 121c, and a first-fourth connection line 121d, but the embodiments of the present specification are not limited thereto.

For example, a plurality of first-first connection lines 121a may be disposed on the second protective layer 113b. The plurality of first-first connection lines 121a may be electrically connected to the pixel driving circuit PD. The plurality of first-first connection lines 121a may transmit a voltage output from the pixel driving circuit PD to the first electrode CE1 or the second electrode CE2.

For example, a third protective layer 114 may be disposed on the second protective layer 113b. The third protective layer 114 may be entirely disposed in the display area AA and the non-display area NA. In the bending area BA, the third protective layer 114 may cover a side surface of the second protective layer 113b and an upper surface of the first protective layer 113a. The third protective layer 114 may be made of an organic insulating material. For example, the third protective layer 114 may be made of photoresist, polyimide (PI), or a photo acryl-based material, but the embodiments of the present specification are not limited thereto. For example, the first protective layer 113a, the second protective layer 113b, and the third protective layer 114 may be made of the same material, but the embodiments of the present specification are not limited thereto. For example, the first protective layer 113a, the second protective layer 113b, and the third protective layer 114 may be insulating layers.

A plurality of first-second connection lines 121b may be disposed on the third protective layer 114. The plurality of first-second connection lines 121b may be connected or directly connected to the pixel driving circuit PD. For example, some of the first-second connection lines 121b may be directly connected to the pixel driving circuit PD through a contact hole of the third protective layer 114. The rest of the first-second connection lines 121b may be electrically connected to the first-first connection line 121a through the contact hole of the third protective layer 114. However, the embodiments of the present specification are not limited thereto. A voltage output from the pixel driving circuit PD may be transmitted to the first electrode CE1 or the second electrode CE2 through the plurality of first-second connection lines 121b and other connection lines.

A first insulating layer 115a may be disposed on the plurality of first-second connection lines 121b. The first insulating layer 115a may be entirely disposed in the display area AA and the non-display area NA, but the embodiments of the present specification are not limited thereto. The first insulating layer 115a may be made of an organic insulating material, but the embodiments of the present specification are not limited thereto. For example, the first insulating layer 115a may be made of photoresist, polyimide (PI), or a photo acryl-based material, but the embodiments of the present specification are not limited thereto.

A plurality of first-third connection lines 121c may be disposed on the first insulating layer 115a. The plurality of first-third connection lines 121c may be electrically connected to the plurality of first-second connection lines 121b. For example, the first-third connection line 121c may be electrically connected to the first-second connection line 121b through a contact hole of the first insulating layer 115a.

A second insulating layer 115b may be disposed on the plurality of first-third connection lines 121c. The second insulating layer 115b may be disposed in the remaining area excluding the bending area BA, but the embodiments of the present specification are not limited thereto. The second insulating layer 115b may be disposed in the display area AA, the first non-display area NA1, and the second non-display area NA2, but the embodiments of the present specification are not limited thereto. For example, one portion of the second insulating layer 115b disposed in the bending area BA may be removed. The second insulating layer 115b may be made of an organic insulating material, but the embodiments of the present specification are not limited thereto. For example, the second insulating layer 115b may be made of photoresist, polyimide (PI), or a photo acryl-based material, but the embodiments of the present specification are not limited thereto.

A plurality of first-fourth connection lines 121d may be disposed on the second insulating layer 115b. The plurality of first-fourth connection lines 121d may be electrically connected to the plurality of first-third connection lines 121c. For example, the first-fourth connection line 121d may be electrically connected to the first-third connection line 121c through a contact hole of the second insulating layer 115b.

According to the present specification, the plurality of first connection lines 121 may be made of titanium (Ti)/aluminum (Al)/titanium (Ti), but the embodiments of the present specification are not limited thereto.

According to the present specification, the plurality of first connection lines 121 may be disposed alternately with each other on different layers with a plurality of insulating layers 115 a to 115c disposed therebetween. An insulating layer adjacent to the plurality of banks BNK each disposed on one of the plurality of light emitting diodes among the plurality of insulating layers may be not disposed in the bending area BA. A thickness of the insulating layer adjacent to the plurality of banks BNK each disposed on one of the plurality of light emitting diodes among the plurality of insulating layers and a thickness of an insulating layer disposed on the pixel driving circuit PD may each be thicker than a thickness of an insulating layer disposed between the plurality of banks BNK and the pixel driving circuits PD. The plurality of first connection lines 121 may be disposed in a staircase shape or a zigzag shape with the plurality of insulating layers 115a to 115c disposed therebetween. For example, the plurality of first-second connection lines 121b may be disposed on a different layer from the plurality of first-third connection lines 121c with the first insulating layer 115a disposed therebetween. The plurality of first-second connection lines 121b may be disposed alternately with the plurality of first-third connection lines 121c with the first insulating layer 115a disposed therebetween. For example, the plurality of first-third connection lines 121c may be disposed on a different layer from the plurality of first-fourth connection lines 121d with the second insulating layer 115b disposed therebetween. The plurality of first-third connection lines 121c may be disposed alternately with the plurality of first-fourth connection lines 121d with the second insulating layer 115b disposed therebetween. Thus, since the plurality of first connection lines 121 are disposed alternately with each other on different layers with the plurality of insulating layers 115a to 115c disposed therebetween, penetration of moisture into the plurality of first connection lines 121 can be prevented or suppressed. In addition, oxidation of aluminum (Al) in titanium (Ti)/aluminum (Al)/titanium (Ti) constituting the plurality of first connection lines 121 due to penetration of moisture into the plurality of first connection lines 121 can be prevented or suppressed, and corrosion of the plurality of first connection lines 121 due to oxidation of aluminum (Al) can be prevented or suppressed.

According to the present specification, in the non-display area NA, a plurality of second connection lines 122 may be disposed on the second protective layer 113b. The plurality of second connection lines 122 may be lines for transmitting a signal, which is transmitted from the flexible circuit board (or flexible film) CB and the printed circuit board 160 (see FIG. 1) to the pad portion PAD, to the pixel driving circuit PD of the display area AA. For example, the plurality of second connection lines 122 may be electrically connected to the plurality of pad electrodes PE and may receive a signal from the flexible circuit board (or flexible film) CB and the printed circuit board. The second connection line 122 may be disposed on the same layer as a connection line disposed on the pixel driving circuit PD.

For example, the plurality of second connection lines 122 may extend from the pad portion PAD toward the display area AA and may transmit a signal to a line of the display area AA. In this case, the plurality of second connection lines 122 may serve as link lines LL. The plurality of second connection lines 122 may include a second-first connection line 122a, a second-second connection line 122b, a second-third connection line 122c, and a second-fourth connection line 122d.

A plurality of second-first connection lines 122a may be disposed on the second protective layer 113b. The plurality of second-first connection lines 122a may extend from the second non-display area NA2 to the bending area BA and the first non-display area NA1. The plurality of second-first connection lines 122a may transmit a signal, which is transmitted from the flexible circuit board (or flexible film) CB and the printed circuit board to the pad portion PAD, to the pixel driving circuit PD of the display area AA.

A plurality of second-second connection lines 122b may be disposed on the third protective layer 114. The plurality of second-second connection lines 122b may be disposed in the second non-display area NA2. The second-second connection line 122b may be electrically connected to the second-first connection line 122a through a contact hole of the third protective layer 114. Therefore, a signal from the flexible circuit board (or flexible film) CB and the printed circuit board can be transmitted to the second-first connection line 122a through the second-second connection line 122b.

The second-third connection line 122c may be disposed on the first insulating layer 115a. The second-third connection line 122c may be disposed in the second non-display area NA2. The second-third connection line 122c may be electrically connected to the second-second connection line 122b through a contact hole of the first insulating layer 115a. Therefore, a signal from the flexible circuit board (or flexible film) CB and the printed circuit board can be transmitted to the second-first connection line 122a through the second-third connection line 122c and the second-second connection line 122b.

The second-fourth connection line 122d may be disposed on the second insulating layer 115b. The second-fourth connection line 122d may be disposed in the second non-display area NA2. The second-fourth connection line 122d may be electrically connected to the second-third connection line 122c through a contact hole of the second insulating layer 115b. Therefore, a signal from a flexible circuit board (or flexible film) CB and a printed circuit board can be transmitted to the second-first connection line 122a through the second-fourth connection line 122d, the second-third connection line 122c, and the second-second connection line 122b.

The plurality of first connection lines 121 and the plurality of second connection lines 122 may be formed of a conductive material with excellent flexibility or any one of various conductive materials used in the display area AA. For example, the second connection line 122 disposed on one portion of the bending area BA may be made of a conductive material with excellent flexibility such as gold (Au), silver (Ag), or aluminum (Al), but the embodiments of the present specification are not limited thereto. In another example, the plurality of first connection lines 121 and the plurality of second connection lines 122 may be made of molybdenum (Mo), chromium (Cr), titanium (Ti), nickel (Ni), neodymium (Nd), copper (Cu), an alloy of silver (Ag) and magnesium (Mg), or an alloy thereof, but the embodiments of the present specification are not limited thereto.

A third insulating layer 115c may be disposed on the plurality of first connection lines 121 and the plurality of second connection lines 122. The third insulating layer 115c may be disposed in the remaining area excluding the bending area BA, but the embodiments of the present specification are not limited thereto. The third insulating layer 115c may be disposed in the display area AA, the first non-display area NA1, and the second non-display area NA2. One portion of the third insulating layer 115c present in the bending area BA may be removed. The third insulating layer 115c may be made of an organic insulating material, but the embodiments of the present specification are not limited thereto. For example, the third insulating layer 115c may be made of photoresist, polyimide (PI), or a photo acryl-based material, but the embodiments of the present specification are not limited thereto.

A plurality of banks BNK may be disposed on the third insulating layer 115c in the display area AA. The plurality of banks BNK may be disposed to each overlap one of the plurality of subpixels. One or more light emitting diodes ED of the same type may be disposed on an upper portion of each of the plurality of banks BNK.

The plurality of signal lines TL may be disposed on the third insulating layer 115c in the display area AA. The plurality of signal lines TL may be disposed in areas between the plurality of banks BNK. For example, the plurality of signal lines TL may be disposed adjacent to any one of the plurality of banks BNK.

The plurality of contact electrodes CCE may be disposed on the third insulating layer 115c in the display area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend from the signal line TL adjacent thereto toward an upper portion of the bank BNK. The first electrode CE1 may be disposed on an upper surface of the bank BNK and a side surface of the bank BNK. For example, the first electrode CE1 may be disposed to extend from the signal line TL on the upper surface of the third insulating layer 115c to the side surface of the bank BNK and the upper surface of the bank BNK.

The first optical layer 117a may be disposed around the plurality of light emitting diodes ED in the display area AA. For example, the first optical layer 117a may surround the plurality of light emitting diodes ED. For example, the first optical layer 117a may be disposed to cover a plurality of light emitting diodes ED and a bank BNK in areas of the plurality of subpixels. For example, the first optical layer 117a may cover a bank BNK, a portion of a second passivation layer 116b, and portions between a plurality of light emitting diodes ED. The second passivation layer 116b may be disposed between the pixel driving circuit PD and the light emitting diode ED. The bank BNK may be disposed between the pixel driving circuit PD and the second passivation layer 116b. The first optical layer 117a may be disposed between or cover portions between a plurality of light emitting diodes ED and a plurality of banks BNK included in a single pixel PX. For example, the first optical layer 117a may be disposed to extend in the first direction X and be spaced in the second direction Y. For example, the first optical layer 117a may be disposed to surround side portions of the light emitting diodes ED and the banks BNK between the second passivation layer 116b and the second electrode CE2, but the embodiments of the present specification are not limited thereto. For example, the first optical layer 117a may be a diffusion layer, a sidewall diffusion layer, or the like, but the embodiments of the present specification are not limited thereto.

The first optical layer 117a may include an organic insulating material in which fine particles are dispersed, but the embodiments of the present specification are not limited thereto. For example, the first optical layer 117a may be made of siloxane in which fine metal particles such as titanium dioxide (TiO₂) particles are dispersed, but the embodiments of the present specification are not limited thereto. Light from the plurality of light emitting diodes ED may be scattered due to the fine particles dispersed in the first optical layer 117a and may be released to the outside of the display apparatus 1000. Thus, the first optical layer 117a can improve extraction efficiency of light emitted from the plurality of light emitting diodes ED.

For example, the first optical layer 117a may be disposed on each of the plurality of pixels PX or may be disposed together on some pixels PX disposed in the same row, but the embodiments of the present specification are not limited thereto. For example, the first optical layer 117a may be disposed on each of the plurality of pixels PX, or the plurality of pixels PX may share one first optical layer 117a. In another example, the plurality of subpixels may each separately include the first optical layer 117a, but the embodiments of the present specification are not limited thereto.

As shown in the plan views of FIGS. 7 to 16 described above, the third optical layer 117c may be disposed between first optical layers 117a. The third optical layer 117c may be disposed on the second passivation layer 116b in the display area AA. For example, the third optical layer 117c may be present around the first optical layer 117a. For example, the third optical layer 117c may be disposed to surround the first optical layer 117a. For example, the third optical layer 117c may abut a side surface of the first optical layer 117a. For example, the third optical layer 117c may be disposed in an area between a plurality of pixels PX. However, the embodiments of the present specification are not limited thereto. For example, the third optical layer 117c may be a diffusion layer, a diffusion layer window, a window diffusion layer, or the like, but the embodiments of the present specification are not limited thereto.

The third optical layer 117c may be made of an organic insulating material, but the embodiments of the present specification are not limited thereto. The third optical layer 117c may be made of the same material as the first optical layer 117a, but the embodiments of the present specification are not limited thereto. For example, the third optical layer 117c may not include fine particles while the first optical layer 117a includes fine particles. For example, the third optical layer 117c may be made of siloxane, but the embodiments of the present specification are not limited thereto.

For example, a thickness of the first optical layer 117a may be smaller than a thickness of the third optical layer 117c, but the embodiments of the present specification are not limited thereto. Accordingly, in a plan view, an area in which the first optical layer 117a is disposed may include a concave portion that is recessed inward from an upper surface of the third optical layer 117c.

According to the present specification, the second electrode CE2 may be disposed on the first optical layer 117a and the third optical layer 117c. For example, the second electrode CE2 may be electrically connected to the plurality of contact electrodes CCE through a contact hole of the third optical layer 117c. For example, the second electrode CE2 may be disposed on the plurality of light emitting diodes ED. For example, the second electrode CE2 may include a transparent conductive oxide such as indium tin oxide (ITO) or indium zinc oxide (IZO), but the embodiments of the present specification are not limited thereto. For example, the second electrode CE2 may be disposed to come into contact with the cathode electrode 135 (see FIG. 29). For example, the second electrode CE2 may overlap the first optical layer 117a. For example, the second electrode CE2 may cover a flat surface of an outer side of the first optical layer 117a.

The second electrode CE2 may continuously extend in the first direction X of the substrate 110. Accordingly, the second electrode CE2 may be connected in common to the plurality of pixels PX arranged in the first direction X of the substrate 110. For example, the second electrode CE2 may be connected in common to the plurality of pixels PX.

According to the present specification, the second electrode CE2 may continuously extend on the first optical layer 117a, the third optical layer 117c, and the light emitting diode ED. The area in which the first optical layer 117a is disposed may include a concave portion that is recessed inward from the upper surface of the third optical layer 117c. Accordingly, since a first portion of the second electrode CE2 disposed on the first optical layer 117a is disposed along the concave portion, the first portion may be disposed at a lower position than a second portion of the second electrode CE2 disposed on the third optical layer 117c.

The second optical layer 117b may be disposed on the second electrode CE2. The second optical layer 117b may be disposed to overlap the plurality of light emitting diodes ED and the first optical layer 117a. Since the second optical layer 117b is disposed on upper portions of the second electrode CE2 and the plurality of light emitting diodes ED, mura that may occur in some of the plurality of light emitting diodes ED can be addressed. For example, when the plurality of light emitting diodes ED are transferred onto the substrate 110 of the display apparatus 1000, an area in which gaps between the plurality of light emitting diodes ED are not uniform may be generated due to process variation or the like. When the gaps between the plurality of light emitting diodes ED are not uniform, a light output area of each of the plurality of light emitting diodes ED may be disposed in a non-uniform manner, and thus mura may be visible to a user. Accordingly, since the second optical layer 117b configured to uniformly diffuse light is configured on upper portions of the plurality of light emitting diodes ED, a phenomenon in which light emitted from some of the light emitting diodes ED is viewed as mura can be reduced. Therefore, since the second optical layer 117b allows light emitted from the plurality of light emitting diodes ED to be evenly diffused and extracted to the outside of the display apparatus 1000, brightness uniformity of the display apparatus 1000 can be improved.

The second optical layer 117b may be made of an organic insulating material in which fine particles are dispersed, but the embodiments of the present specification are not limited thereto. For example, the second optical layer 117b may be made of siloxane in which fine metal particles such as titanium dioxide (TiO₂) particles are dispersed, but the embodiments of the present specification are not limited thereto. For example, the second optical layer 117b may be made of the same material as the first optical layer 117a, but the embodiments of the present specification are not limited thereto. For example, the second optical layer 117b may be a diffusion layer, an upper surface diffusion layer, or the like, but the embodiments of the present specification are not limited thereto.

According to the present specification, light from the plurality of light emitting diodes ED may be scattered due to the fine particles dispersed in the second optical layer 117b and may be released to the outside of the display apparatus 1000. The second optical layer 117b may evenly mix light emitted from the plurality of light emitting diodes ED and may further improve brightness uniformity of the display apparatus 1000. In addition, the light extraction efficiency of the display apparatus 1000 can be improved by the light scattered from the plurality of fine particles, and thus the display apparatus 1000 can operate with low power.

According to the present specification, a first passivation layer 116a may be disposed on the first optical layer 117a. Alternatively, the first passivation layer 116a may be disposed on the second optical layer 117b. Alternatively, the first passivation layer 116a may be disposed on the third optical layer 117c. For example, the first passivation layer 116a may be disposed in the display area AA and the first non-display area NA1. Since the first passivation layer 116a is disposed to cover the first optical layer 117a, the second optical layer 117b, and/or the third optical layer 117c disposed in the display area AA and the first non-display area NA1, penetration of moisture or impurities into the first optical layer 117a, the second optical layer 117b, and/or the third optical layer 117c can be reduced. For example, the first passivation layer 116a may be made of a single layer or multiple layers of silicon oxide (SiOx) or silicon nitride (SiNx), but the embodiments of the present specification are not limited thereto. For example, the first passivation layer 116a may be a protective layer, an insulating layer, or the like, but the embodiments of the present specification are not limited thereto.

A thickness of the first passivation layer 116a may be different from a thickness of the second passivation layer 116b. The thickness of the first passivation layer 116a may be thicker than the thickness of the second passivation layer 116b, but the embodiments of the present specification are not limited thereto. Since the first optical layer 117a is made of a material in which fine particles are dispersed, mura may occur due to diffusion of fine particles at the time of forming the first optical layer 117a. Accordingly, mura due to the first optical layer 117a can be prevented or reduced by the first passivation layer 116a. In addition, by making the thickness of the first passivation layer 116a thicker than the thickness of the second passivation layer 116b, mura due to the first optical layer 117a can be prevented or reduced. For example, the thickness of the first passivation layer 116a may range from 3,000 Å to 5,000 Å, but the embodiments of the present specification are not limited thereto. For example, the thickness of the second passivation layer 116b may range from 500 Å to 1,500 Å. Alternatively, the thickness of the second passivation layer 116b may range from 800 Å to 1,200 Å. However, the embodiments of the present specification are not limited thereto.

A black matrix BM may be disposed on the second electrode CE2, the first optical layer 117a, the third optical layer 117c, and the second optical layer 117b in the display area AA. For example, the black matrix BM may fill a contact hole of the third optical layer 117c. Since the black matrix BM is configured to cover the display area AA, color mixture and external light reflection of light of the plurality of subpixels can be reduced. For example, since the black matrix BM is also disposed in a contact hole in which the second electrode CE2 and the contact electrode CCE are connected, light leakage between the plurality of subpixels neighboring each other can be prevented or reduced.

For example, the black matrix BM may be made of an opaque material, but the embodiments of the present specification are not limited thereto. For example, the black matrix BM may be an organic insulating material to which a black pigment or a black dye is added, but the embodiments of the present specification are not limited thereto.

A cover layer 118 may be disposed on the black matrix BM in the display area AA. The cover layer 118 may protect components under the cover layer 118. For example, the cover layer 118 may be made of an organic insulating material, but the embodiments of the present specification are not limited thereto. For example, the cover layer 118 may be made of photoresist, polyimide (PI), or a photo acryl-based material, but the embodiments of the present specification are not limited thereto. For example, the cover layer 118 may be an overcoating layer, an insulating layer, or the like, but the embodiments of the present specification are not limited thereto.

The polarizing layer 293 may be disposed on the cover layer 118 via a first adhesive layer 291. The cover member 120 may be disposed on the polarizing layer 293 via a second adhesive layer 295. For example, the first adhesive layer 291 and the second adhesive layer 295 may include an optically cleared adhesive (OCA), an optically cleared resin (OCR), a pressure sensitive adhesive (PSA), or the like, but the embodiments of the present specification are not limited thereto.

According to the present specification, the plurality of pad electrodes PE may be disposed on the third insulating layer 115c in the second non-display area NA2. For example, at least one portion of the plurality of pad electrodes PE may be exposed from the second passivation layer 116b. For example, the plurality of pad electrodes PE may be electrically connected to the second-fourth connection line 122d through a contact hole of the third insulating layer 115c.

An adhesive layer ACF may be disposed on the plurality of pad electrodes PE. The adhesive layer ACF may be an adhesive layer in which conductive balls are dispersed in an insulating material, but the embodiments of the present specification are not limited thereto. When heat or pressure is applied to the adhesive layer ACF, the conductive balls may be electrically connected and have a conductive characteristic at a portion to which heat or pressure is applied. The adhesive layer ACF may be disposed between the plurality of pad electrodes PE and the flexible circuit board (or flexible film) CB to attach or bond the flexible circuit board (or flexible film) CB to the plurality of pad electrodes PE. For example, the adhesive layer ACF may be an anisotropic conductive film (ACF), but the embodiments of the present specification are not limited thereto.

The flexible circuit board (or flexible film) CB may be disposed on the adhesive layer ACF. The flexible circuit board (or flexible film) CB may be electrically connected to the plurality of pad electrodes PE through the adhesive layer ACF. Therefore, a signal output from the flexible circuit board (or flexible film) CB and the printed circuit board may be transmitted to the pixel driving circuit PD of the display area AA through the plurality of pad electrodes PE, the second-fourth connection line 122d, the second-third connection line 122c, the second-second connection line 122b, and the second-first connection line 122a.

As shown in FIG. 21, the first electrode CE1 and the plurality of light emitting diodes 130, 140, and 150 may be disposed in the dummy area DUA. The second electrode CE2 may not be disposed in the dummy area DUA. Therefore, in the dummy area DUA, a cathode voltage may not be supplied through the second electrode CE2, and the light emitting diodes 130, 140, and 150 may not be able to emit light. In addition, the second optical layer 117b may not be disposed in the dummy area DUA, but the present specification is not limited thereto.

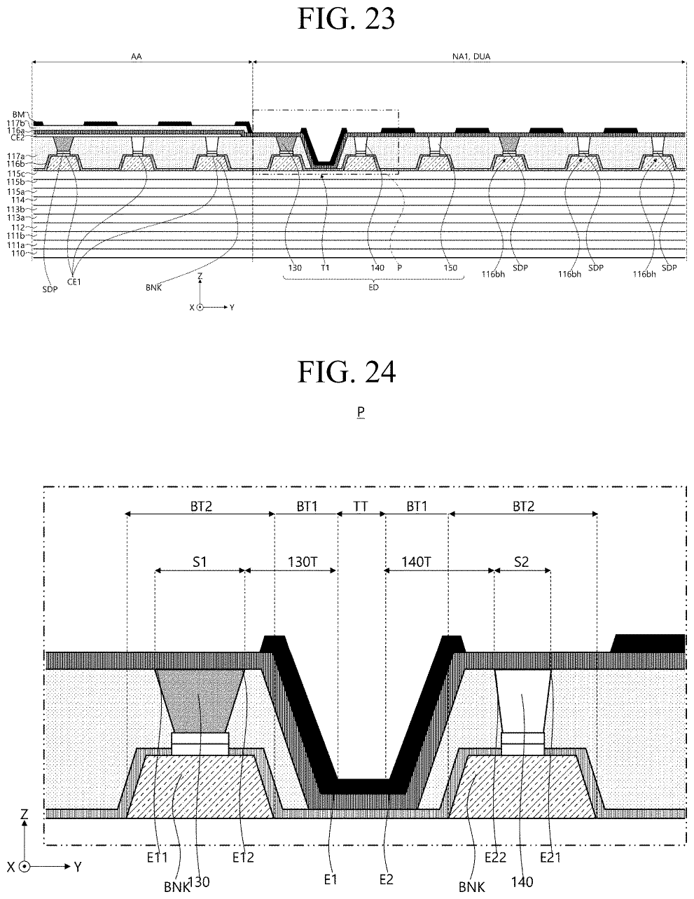

FIGS. 23 to 28 are cross-sectional views illustrating the display apparatus according to an example embodiment of the present specification. Components that perform substantially the same functions as in the above-described embodiments will be denoted by the same reference numerals, and detailed description thereof may be omitted.

FIG. 23 is a cross-sectional view corresponding to the display apparatus according to the first example embodiment. FIG. 24 is a partially enlarged view showing portion P of FIG. 23 in an enlarged manner.

As shown in FIGS. 23 and 24, the display apparatus may include the plurality of light emitting diodes 130, 140, and 150 disposed in the display area AA and the first non-display area NA1. The first optical layer 117a may be disposed between the plurality of light emitting diodes 130, 140, and 150. The first optical layer 117a may be present around the plurality of light emitting diodes 130, 140, and 150. For example, the first optical layer 117a may surround the plurality of light emitting diodes 130, 140, and 150. The second optical layer 117b may be disposed on the first optical layer 117a. The second optical layer 117b may be disposed in the display area AA and the dummy area DUA. In an area of the first non-display area NA1 where the second optical layer 117b is not disposed, a thickness (for example, a length in the Z-axis direction) formed by an optical layer may be smaller than the thickness in the dummy area DUA.

The first passivation layer 116a may be disposed on the first optical layer 117a. The second optical layer 117b may be disposed on the first passivation layer 116a, or the first passivation layer 116a may also be disposed on the second optical layer 117b (not shown). The first passivation layer 116a may be formed on at least one portion of the display area AA and the first non-display area NA1. The first passivation layer 116a may be formed to cover the display area AA and the first non-display area NA1 on the first optical layer 117a and/or the second optical layer 117b. For example, the first passivation layer 116a may be formed to entirely cover the display area AA and the first non-display area NA1 on the first optical layer 117a and/or the second optical layer 117b. For example, the first passivation layer may be disposed across the display area AA and the first non-display area NA1. Since the display apparatus 1000 according to the embodiment of the present specification includes the first passivation layer 116a and the first trench T1, permeation of moisture from the outside of the display apparatus can be prevented or suppressed, and the service life of the display apparatus may increase. Thus, it is possible to provide a display apparatus whose power consumption is reduced and which can be operated with low power.

According to the present specification, the first optical layer 117a and/or the second optical layer 117b may be protected by the first passivation layer 116a. Accordingly, since the display apparatus can be protected from penetration of moisture from the outside, the reliability of the display apparatus can be improved.

The second passivation layer 116b may be formed to cover the bank BNK on which the plurality of light emitting diodes 130, 140, and 150 are disposed. The second passivation layer 116b may include a hole 116bh through which a solder pattern SDP is exposed. Since the display apparatus according to the embodiment of the present specification further includes the second passivation layer 116b protecting a lower portion of the bank BNK and the first passivation layer 116a protecting the first optical layer 117a and/or the second optical layer 117b, the display apparatus can be protected from moisture or the like from the outside, and accordingly, the service life of the display apparatus may increase.

As shown in FIG. 23, the display apparatus may include the first trench T1. With respect to the coordinate system, the first trench T1 may be disposed to extend in the first direction (for example, the X-axis direction). The first non-display area NA1 may include the first trench T1. The dummy area DUA may include the first trench T1. The first trench T1 may be formed between the plurality of light emitting diodes 130, 140, and 150. The first trench T1 may be formed between a plurality of dummy light emitting diodes (a plurality of light emitting diodes disposed in the dummy area DUA).

For example, if a thickness of the first passivation layer 116a is too thick, a warpage phenomenon may occur at a portion where the first trench T1 is present. In addition, a deposition time and/or the time taken for an etching (for example, dry etching) process may increase, causing a turnaround time (TAT) to increase.

For example, if the thickness of the first passivation layer 116a is too thin, there is a problem that fine particles included in the first optical layer 117a present on a portion of the first trench T1 where a slope is formed are not able to be fixed to the corresponding slope surface.

In one embodiment, the thickness of the first passivation layer 116a may range from 3,000 Å to 5,000 Å, but the embodiments of the present specification are not limited thereto. Thus, there are advantages that the warpage phenomenon can be prevented or suppressed, and the fine particles can be efficiently fixed to the slope surface.

For example, if a width of the first trench T1 is too short, an angle of inclination of the first trench T1 is too steep, and thus the first passivation layer 116a may not be formed or deposited on the first trench T1.

For example, if the width of the first trench T1 is too long, the first optical layer 117a may not be able to protect the light emitting diode ED after the light emitting diode ED is transferred and the first optical layer 117a is formed or deposited. Accordingly, in a subsequent process, the light emitting diode ED may be lost without being properly fixed or formed.

The first optical layer 117a formed in the first non-display area NA1 and/or the dummy area DUA may include the first trench T1. The second optical layer 117b formed in the first non-display area NA1 and/or the dummy area DUA may include the first trench T1. The first trench T1 may be formed by removing at least one portion of the first optical layer 117a and/or the second optical layer 117b. The first passivation layer 116a may be disposed on the first trench T1. At least one portion of the black matrix BM may be disposed on the first trench T1.

As shown in FIG. 24, the first trench T1 may include a first end E1 and a second end E2 that face each other. The first light emitting diode 130 may include an eleventh end E11 relatively far from the first end E1 and a twelfth end E12 relatively close to the first end E1. The second light emitting diode 140 may include a twenty-first end E21 relatively far from the second end E2 and a twenty-second end E22 relatively close to the second end E2. For example, the end may be one side, but the present specification is not limited thereto.

A distance BT1 from the first end E1 to one end (or one side) of the bank BNK where the first light emitting diode 130 is disposed and a distance BT1 from the second end E2 to one end (or one side) of the bank BNK where the second light emitting diode 140 is disposed may be substantially the same. A distance BT2 from the one end (or one side) of the bank BNK where the first light emitting diode 130 is disposed to the other end (or other side) and a distance BT2 from the one end (or one side) of the bank BNK where the second light emitting diode 140 is disposed to the other end (or other side) may be substantially the same. A distance TT between the first end E1 and the second end E2 may be smaller than the distance BT1 from the first end E1 or the second end E2 to the one end (or one side) of the bank BNK where the corresponding light emitting diode is disposed. The distance TT between the first end E1 and the second end E2 may be smaller than the distance BT2 from the one end (or one side) of the bank BNK where the light emitting diode is disposed to the other end (or other side).

The first light emitting diode 130 may have a first size. The first size may be proportional to a distance S1 between the eleventh end E11 and the twelfth end E12. The second light emitting diode 140 may have a second size. The second size may be proportional to a distance S2 between the twenty-first end E21 and the twenty-second end E22. The second size may be different from the first size. The second size may be smaller than the first size. Since the first size is formed to be relatively larger, the light efficiency of the first light emitting diode 130 may be improved. Since the first size is formed to be larger than the second size, a distance 130T between the first end E1 and the twelfth end E12 may be smaller than a distance 140T between the second end E2 and the twenty-second end E22.

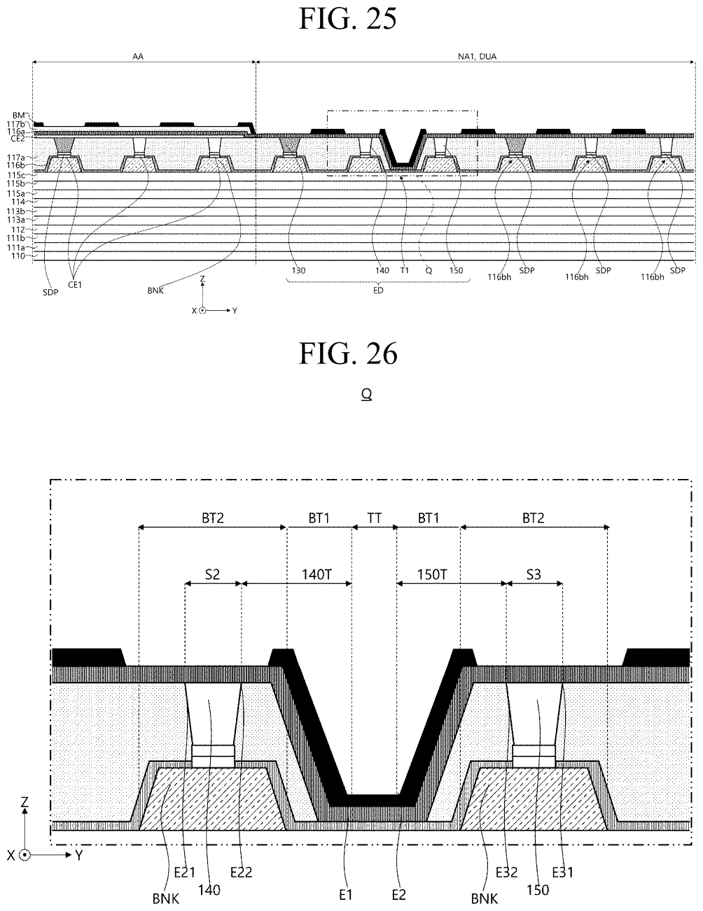

FIG. 25 is a cross-sectional view corresponding to the display apparatus according to the third example embodiment. FIG. 26 is a partially enlarged view showing portion Q of FIG. 25 in an enlarged manner.

As shown in FIG. 26, the first trench T1 may include a first end E1 and a second end E2 that face each other. The second light emitting diode 140 may include a twenty-first end E21 relatively far from the first end E1 and a twenty-second end E22 relatively close to the first end E1. The third light emitting diode 150 may include a thirty-first end E31 relatively far from the second end E2 and a thirty-second end E32 relatively close to the second end E2.

A distance BT1 from the first end E1 to one end (or one side) of the bank BNK where the second light emitting diode 140 is disposed and a distance BT1 from the second end E2 to one end (or one side) of the bank BNK where the third light emitting diode 150 is disposed may be substantially the same. A distance BT2 from the one end (or one side) of the bank BNK where the second light emitting diode 140 is disposed to the other end (or other side) and a distance BT2 from the one end (or one side) of the bank BNK where the third light emitting diode 150 is disposed to the other end (or other side) may be substantially the same. A distance TT between the first end E1 and the second end E2 may be smaller than the distance BT1 from the first end E1 or the second end E2 to the one end (or one side) of the bank BNK where the corresponding light emitting diode is disposed. The distance TT between the first end E1 and the second end E2 may be smaller than the distance BT2 from the one end (or one side) of the bank BNK where the light emitting diode is disposed to the other end (or other side).

The second light emitting diode 140 may have a second size. The second size may be proportional to a distance S2 between the twenty-first end E21 and the twenty-second end E22. The third light emitting diode 150 may have a third size. The third size may be proportional to a distance S3 between the thirty-first end E31 and the thirty-second end E32. The third size may be substantially the same as the second size. By placing the first trench T1 between the second light emitting diode 140 and the third light emitting diode 150, a distance 140T between the first end E1 and the twenty-second end E22 may be larger as compared to the example embodiment according to FIG. 24 described above. Therefore, since a design margin for a light emitting diode can be secured, the probability of defective transfer of a light emitting diode can be reduced in a process of manufacturing the display panel. Thus, the productivity of the display apparatus can be further improved.

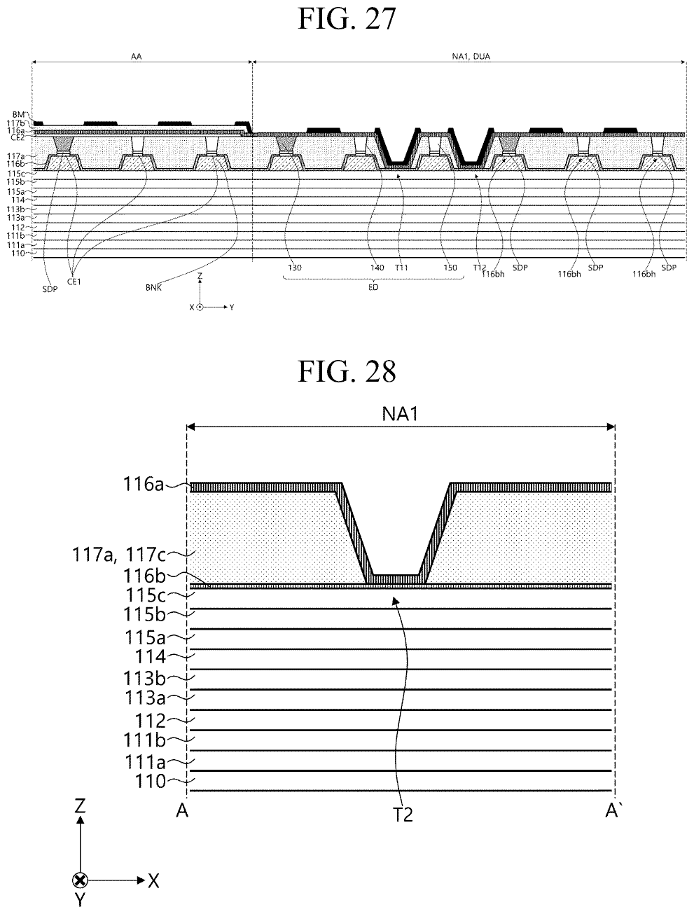

FIG. 27 is a cross-sectional view corresponding to the display apparatus according to the sixth example embodiment. FIG. 28 is a cross-sectional view along line A-A′ in FIG. 13. Components that perform substantially the same functions as in the above-described embodiments will be denoted by the same reference numerals, and detailed description thereof may be omitted.

As shown in FIG. 27, the display apparatus may include a plurality of trenches T11 and T12. The eleventh trench T11 may be disposed between the second light emitting diode 140 and the third light emitting diode 150. The twelfth trench T12 may be disposed between the third light emitting diode 150 and the first light emitting diode 130.

As shown in FIG. 28, the display apparatus may include the first optical layer 117a. The second trench T2 may be formed by removing at least one portion of the first optical layer 117a. With reference to the plan view corresponding to the sixth embodiment, a light emitting diode may not be disposed on the bending area. In addition, since an area in which the second optical layer extends is substantially the same as an area in which the second electrode extends, the display apparatus may not include the second optical layer. Therefore, a thickness (for example, a length in the Z-axis direction) may be smaller than that of an area in which the second optical layer is formed.

According to the present specification, the first passivation layer 116a may be disposed across the display area AA and the first non-display area NA1. Since the display apparatus according to the embodiment of the present specification is configured to include the first passivation layer 116a and the second trench T2, permeation of moisture from the outside of the display apparatus can be prevented or suppressed, and the service life of the display apparatus may increase. Thus, it is possible to provide a display apparatus whose power consumption is reduced and which can be operated with low power.

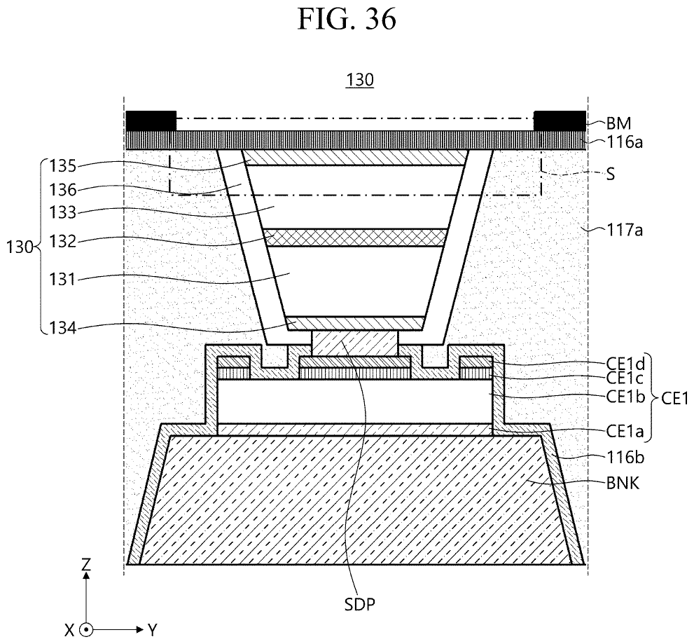

FIG. 29 is a cross-sectional view illustrating the display apparatus according to an example embodiment of the present specification. FIG. 36 is a cross-sectional view illustrating the display apparatus according to an example embodiment of the present specification.

FIG. 29 is a cross-sectional view illustrating a subpixel including a light emitting diode disposed in the display area AA.

FIG. 36 is a cross-sectional view illustrating a subpixel including a light emitting diode disposed in the dummy area DUA. Components that perform substantially the same functions will be denoted by the same reference numerals in different cross-sectional views, and detailed description thereof may be omitted.

As shown in FIGS. 29 and 36, the first electrode CE1 may be made of a plurality of conductive layers. For example, the first electrode CE1 may include a first conductive layer CE1a, a second conductive layer CE1b, a third conductive layer CE1c, and a fourth conductive layer CE1d, but the embodiments of the present specification are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may each be made of titanium (Ti), molybdenum (Mo), aluminum (Al), or titanium (Ti) and indium tin oxide (ITO), but the embodiments of the present specification are not limited thereto.

According to the present specification, some conductive layers with good reflection efficiency among the plurality of conductive layers constituting the first electrode CE1 may be configured as an align key and/or a reflector for aligning a light emitting diode ED. For example, the second conductive layer CE1b among the plurality of conductive layers of the first electrode CE1 may include a reflecting material. For example, the second conductive layer CE1b may include aluminum (Al), but the embodiments of the present specification are not limited thereto. Accordingly, the second conductive layer CE1b may be configured as a reflector. In addition, identification may be easy in the manufacturing process due to high reflection efficiency of the second conductive layer CE1b, and thus the position or transfer position of the light emitting diode ED may be aligned based on the second conductive layer CE1b.

For example, to configure the second conductive layer CE1b as a reflector, the third conductive layer CE1c and the fourth conductive layer CE1d covering the second conductive layer CE1b may be partially removed or etched. For example, an upper surface of the second conductive layer CE1b may be exposed by removing or etching one portion of the third conductive layer CE1c and the fourth conductive layer CE1d disposed on the bank BNK. For example, a central portion and an edge portion of the third conductive layer CE1c and the fourth conductive layer CE1d where the solder pattern SDP is disposed may be left, and the remaining portion excluding the central portion and the edge portion may be removed. For example, an edge portion of each of the third conductive layer CE1c made of titanium (Ti) and the fourth conductive layer CE1d made of indium tin oxide (ITO) may not be etched. Accordingly, corrosion of another conductive layer of the first electrode CE1 due to a tetramethylammonium hydroxide (TMAH) solution used in a process of masking the first electrode CE1 can be prevented or suppressed. For example, the solder pattern SDP may be a pattern layer or a pattern, but is not limited to such terms.

According to the present specification, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) that has good adhesion to the solder pattern SDP and has corrosion resistance and acid resistance. However, the embodiments of the present specification are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the embodiments of the present specification are not limited thereto.

According to the present specification, the signal line TL, the contact electrode CCE, and the pad electrode PE that are disposed on the same layer as the first electrode CE1 may be made of multiple layers of conductive materials, but the embodiments of the present specification are not limited thereto. For example, the signal line TL, the contact electrode CCE, and the pad electrode PE may be made of multiple layers of indium tin oxide (ITO)/titanium (Ti)/aluminum (Al)/titanium (Ti), but the embodiments of the present specification are not limited thereto.

According to the present specification, the solder pattern SDP may be disposed on the first electrode CE1 in each of the plurality of subpixels. The solder pattern SDP may bond the light emitting diode ED to the first electrode CEL. The first electrode CE1 and the light emitting diode ED may be electrically connected through eutectic bonding using the solder pattern SDP, but the embodiments of the present specification are not limited thereto. The first electrode CE1 and the anode electrode 134 of the light emitting diode ED may be electrically connected through eutectic bonding by the solder pattern SDP, but the embodiments of the present specification are not limited thereto. For example, if the solder pattern SDP is made of indium (In), and the anode electrode 134 of the light emitting diode ED is made of gold (Au), the solder pattern SDP and the anode electrode 134 may be bonded by applying heat and pressure in a process of transferring the light emitting diode ED. Through eutectic bonding, the light emitting diode ED may be bonded to the solder pattern SDP and the first electrode CE1 without a separate adhesive material. For example, the solder pattern SDP may be made of indium (In), tin (Sn), or an alloy thereof, but the embodiments of the present specification are not limited thereto. For example, the solder pattern SDP may be a bonding pad, an adhesive pad, or the like, but the embodiments of the present specification are not limited thereto.

According to the present specification, the second passivation layer 116b may be disposed on the plurality of signal lines TL, the plurality of first electrodes CE1, the plurality of contact electrodes CCE, and the third insulating layer 115c. For example, the second passivation layer 116b may be disposed in the display area AA, the first non-display area NA1, and the second non-display area NA2. One portion of the second passivation layer 116b disposed in the bending area BA may be removed. One portion of the second passivation layer 116b covering the plurality of pad electrodes PE in the second non-display area NA2 may be removed. Since the second passivation layer 116b is disposed to cover the remaining area excluding the bending area BA, the plurality of pad electrodes PE, and the area in which the solder pattern SDP is disposed, penetration of moisture or impurities into the light emitting diode ED can be reduced. For example, the second passivation layer 116b may be made of a single layer or multiple layers of silicon oxide (SiOx) or silicon nitride (SiNx), but the embodiments of the present specification are not limited thereto. For example, the second passivation layer 116b may be a protective layer, an insulating layer, or the like, but the embodiments of the present specification are not limited thereto. For example, the second passivation layer 116b may include the hole 116bh through which the solder pattern SDP is exposed.

The light emitting diode ED may be disposed on the solder pattern SDP in each of the plurality of subpixels. The first light emitting diode 130 may be disposed on the first subpixel SP1. The second light emitting diode 140 may be disposed on the second subpixel SP2. The third light emitting diode 150 may be dispose on the third subpixel SP3.

The light emitting diode ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present specification are not limited thereto.

As shown in FIGS. 29 and 36, the first light emitting diode 130 may include an anode electrode 134, a first semiconductor layer 131, an active layer 132, a second semiconductor layer 133, a cathode electrode 135, and an encapsulation layer 136, but the embodiments of the present specification are not limited thereto. For example, the encapsulation layer 136 may not be included in the first light emitting diode 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a compound semiconductor such as a III-V group compound semiconductor or a II-VI group compound semiconductor and may be doped with impurities (or dopants). For example, one of the first semiconductor layer 131 and the second semiconductor layer 133 may be a semiconductor layer doped with n-type impurities, and the other may be a semiconductor layer doped with p-type impurities, but the embodiments of the present specification are not limited thereto. For example, one or more of the first semiconductor layer 131 and the second semiconductor layer 133 may be a layer in which a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs) is doped with n-type or p-type impurities, but the embodiments of the present specification are not limited thereto. For example, the n-type impurities may be silicon (Si), germanium (Ge), selenium (Se), carbon (C), tellurium (Te), or tin (Sn), but the embodiments of the present specification are not limited thereto. For example, the p-type impurities may be magnesium (Mg), zinc (Zn), calcium (Ca), strontium (Sr), barium (Ba), or beryllium (Be), but the embodiments of the present specification are not limited thereto.

For example, the first semiconductor layer 131 and the second semiconductor layer 133 may be a nitride semiconductor including n-type impurities and a nitride semiconductor including p-type impurities, respectively, but the embodiments of the present specification are not limited thereto. For example, the first semiconductor layer 131 may be a nitride semiconductor including p-type impurities, and the second semiconductor layer 133 may be a nitride semiconductor including n-type impurities, but the embodiments of the present specification are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and may emit light. For example, the active layer 132 may be made of one of a single well structure, a multi-well structure, a single quantum well structure, a multi-quantum well (MQW) structure, a quantum dot structure, and a quantum wire structure, but the embodiments of the present specification are not limited thereto. For example, the active layer 132 may be made of indium gallium nitride (InGaN) or gallium nitride (GaN), but the embodiments of the present specification are not limited thereto.

In another example, the active layer 132 may include a multi-quantum well (MQW) structure having a well layer and a barrier layer with a higher band gap than the well layer. For example, the active layer 132 may be made of a well layer made of InGaN and a barrier layer made of an AlGaN, but the embodiments of the present specification are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be made of a conductive material capable of eutectic bonding with the solder pattern SDP, but the embodiments of the present specification are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present specification are not limited thereto.

The cathode electrode 135 may be disposed on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 through the contact electrode CCE, the second electrode CE2, and the cathode electrode 135. The cathode electrode 135 may be made of a transparent conductive material so that light emitted from the light emitting diode ED is directed toward an upper portion of the light emitting diode ED, but the embodiments of the present specification are not limited thereto. For example, the cathode electrode 135 may be made of a material such as indium tin oxide (ITO), indium zinc oxide (IZO), or indium gallium zinc oxide (IGZO), but the embodiments of the present specification are not limited thereto.

The encapsulation layer 136 may be disposed on at least a portion of the first semiconductor layer 131, the active layer 132, the second semiconductor layer 133, the anode electrode 134, and the cathode electrode 135. For example, the encapsulation layer 136 may surround at least a portion of the first semiconductor layer 131, the active layer 132, the second semiconductor layer 133, the anode electrode 134, and the cathode electrode 135.

For example, the encapsulation layer 136 may protect the first semiconductor layer 131, the active layer 132, and the second semiconductor layer 133. For example, the encapsulation layer 136 may be disposed on a side surface of the first semiconductor layer 131, a side surface of the active layer 132, and a side surface of the second semiconductor layer 133.

For example, the encapsulation layer 136 may be disposed on at least a portion of the anode electrode 134 and the cathode electrode 135, for example, an edge portion (or one side) of the anode electrode 134 and an edge portion (or one side) of the cathode electrode 135. At least a portion of the anode electrode 134 may be exposed through the encapsulation layer 136, and the anode electrode 134 and the solder pattern SDP may be connected. For example, at least a portion of the cathode electrode 135 may be exposed through the encapsulation layer 136, and the cathode electrode 135 and the second electrode CE2 may be connected. For example, the encapsulation layer 136 may be made of an insulating material such as silicon nitride (SiNx) or silicon oxide (SiOx), but the embodiments of the present specification are not limited thereto.

In another example, the encapsulation layer 136 may have a structure in which a reflecting material is dispersed in a resin layer, but the embodiments of the present specification are not limited thereto. For example, the encapsulation layer 136 may be manufactured as a reflector of various structures, but the embodiments of the present specification are not limited thereto. Light emitted from the active layer 132 may be reflected upward by the encapsulation layer 136, and light extraction efficiency may be improved. For example, the encapsulation layer 136 may be a reflective layer, but the embodiments of the present specification are not limited thereto.

According to the present specification, the light emitting diode ED has been described as having a vertical type structure, but the embodiments of the present specification are not limited thereto. For example, the light emitting diode ED may have a lateral structure or a flip chip structure.

The first light emitting diode 130 has been described above with reference to FIGS. 29 and 36, but the second light emitting diode 140 and the third light emitting diode 150 may have substantially the same structure as the first light emitting diode 130. For example, the second light emitting diode 140 and the third light emitting diode 150 may each include a first semiconductor layer 131, an active layer 132, a second semiconductor layer 133, an anode electrode 134, a cathode electrode 135, and an encapsulation layer 136 that are substantially the same as those of the first light emitting diode 130. However, the present specification is not limited thereto.

As shown in FIG. 36, the first electrode CE1 and a plurality of light emitting diodes may be disposed in a dummy area. The second electrode CE2 may not be disposed in the dummy area. Therefore, in the dummy area, a cathode voltage may not be supplied through the second electrode CE2, and the light emitting diodes may not be able to emit light. The second optical layer 117b may not be disposed in the dummy area.

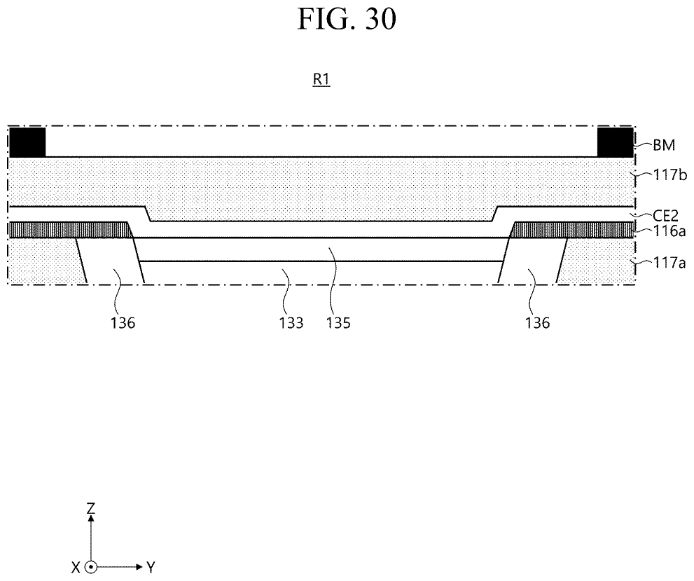

FIGS. 30 to 35 and FIGS. 37 and 38 are cross-sectional views illustrating the display apparatus according to an example embodiment of the present specification.

FIGS. 30 to 35 are partially enlarged views (R1, R2, R3, R4, R5, and R6) showing portion R of FIG. 29 in an enlarged manner. FIGS. 30 to 35 each illustrate a display apparatus according to one of twelfth to seventeenth example embodiments. Components that perform substantially the same functions as in the above-described embodiments will be denoted by the same reference numerals, and detailed description thereof may be omitted.

As shown in FIG. 30, a display apparatus R1 according to the twelfth example embodiment may include a first passivation layer 116a disposed on a first optical layer 117a. A second electrode CE2 may be disposed on the first optical layer 117a. For light emission, the second electrode CE2 may have a structure for coming into contact with a light emitting diode. For example, the second electrode CE2 may have a structure covering the first passivation layer 116a to allow the light emitting diode to come into contact with the second electrode CE2 after at least a portion of the first passivation layer 116a is removed. A second optical layer 117b may be disposed on the second electrode CE2. A black matrix BM may be disposed on the second optical layer 117b.

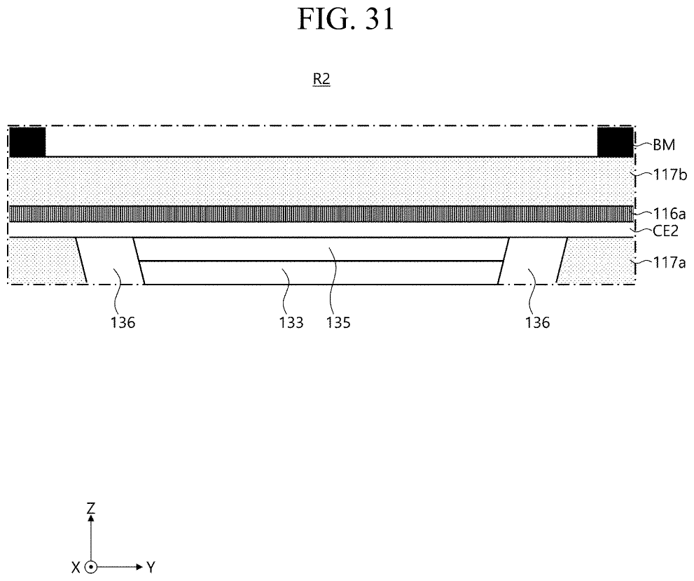

As shown in FIG. 31, a display apparatus R2 according to the thirteenth example embodiment may include a second electrode CE2 disposed on a first optical layer 117a. The second electrode CE2 may come into contact with a light emitting diode. A first passivation layer 116a may be disposed on the second electrode CE2. A second optical layer 117b may be disposed on the first passivation layer 116a. A black matrix BM may be disposed on the second optical layer 117b.

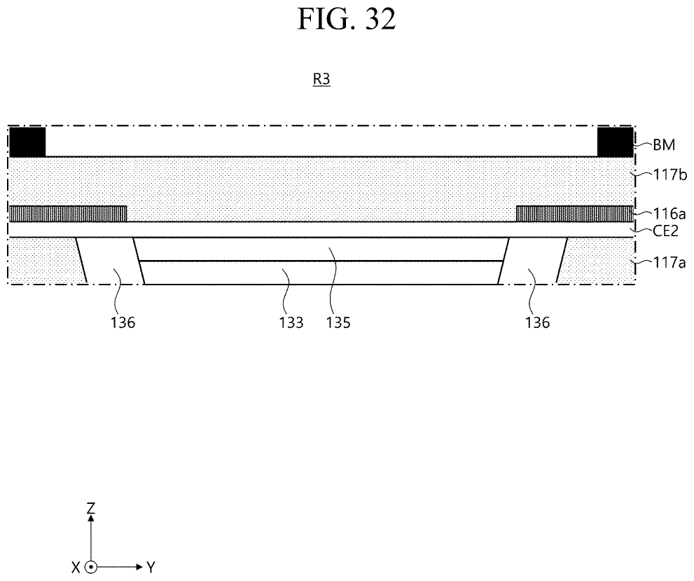

As shown in FIG. 32, in a display apparatus R3 according to the fourteenth example embodiment, at least a portion of a first passivation layer 116a disposed on a second electrode CE2 may be removed. A second optical layer 117b may be disposed on the first passivation layer 116a. A black matrix BM may be disposed on the second optical layer 117b. If the first passivation layer 116a is made of an opaque material, due to the configuration, light from a light emitting diode may pass through the second optical layer 117b without passing through the first passivation layer 116a. Accordingly, light efficiency of the light emitting diode can be improved.

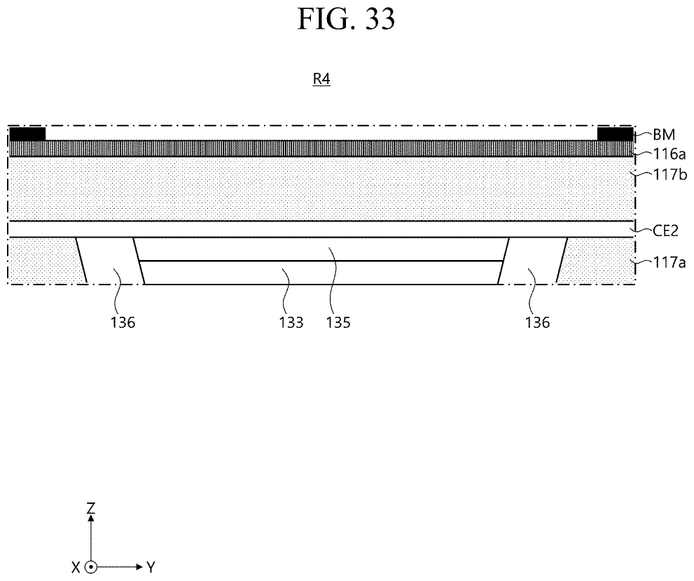

As shown in FIG. 33, a display apparatus R4 according to the fifteenth example embodiment may include a first passivation layer 116a disposed on a second optical layer 117b. The second optical layer 117b may be disposed on a second electrode CE2. A black matrix BM may be disposed on the first passivation layer 116a. Accordingly, the first passivation layer 116a can be protected by both a first optical layer 117a and the second optical layer 117b, the reliability of the display apparatus can be improved, and a color reproduction range can be improved. The black matrix BM may be disposed on the first passivation layer 116a.

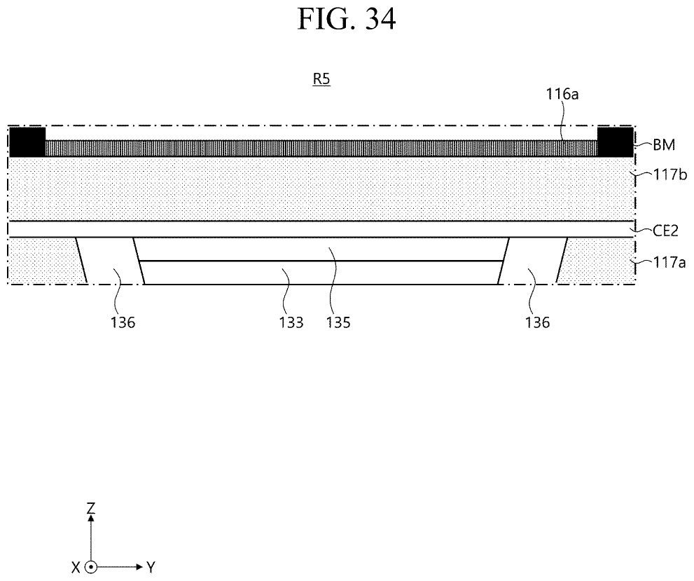

As shown in FIG. 34, in a display apparatus R5 according to the sixteenth example embodiment, a second electrode CE2 may be disposed on a first optical layer 117a. A second optical layer 117b may be disposed on the second electrode CE2. A first passivation layer 116a and a black matrix BM may be disposed on the second optical layer 117b. The black matrix BM may be disposed around the first passivation layer 116a or on an edge thereof. If the first passivation layer 116a is formed of a transparent material, due to the configuration, visibility issue due to the black matrix BM can be improved.

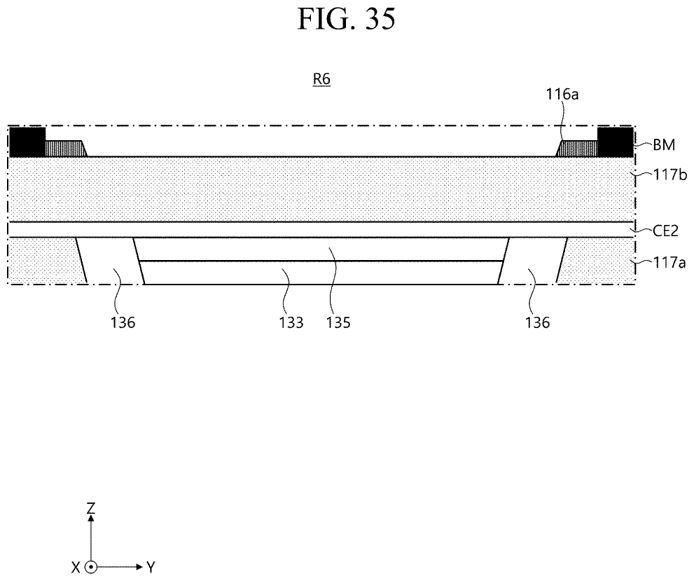

As shown in FIG. 35, in a display apparatus R6 according to the seventeenth example embodiment, a second electrode CE2 may be disposed on a first optical layer 117a. A second optical layer 117b may be disposed on the second electrode CE2. At least a portion of a first passivation layer 116a disposed on the second optical layer 117b may be removed. A black matrix BM may be disposed around the first passivation layer 116a or on an edge thereof. If the first passivation layer 116a is formed of an opaque material, due to the configuration, light from a light emitting diode may not pass through the first passivation layer 116a. Accordingly, luminous efficiency of the display apparatus may increase.

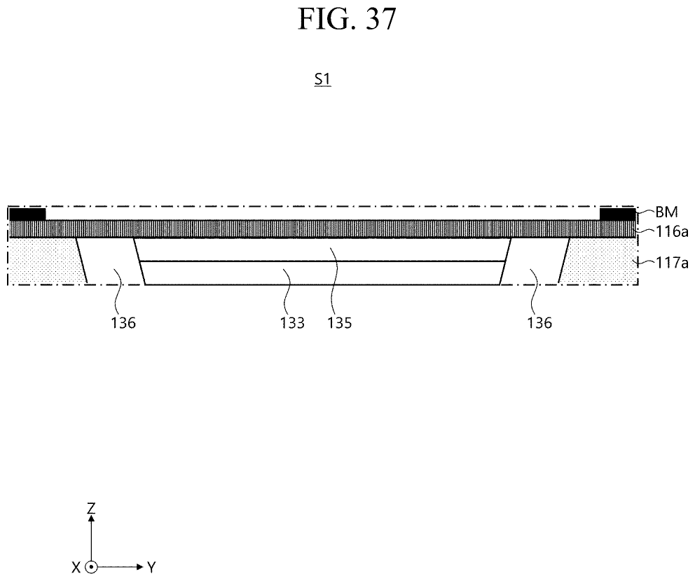

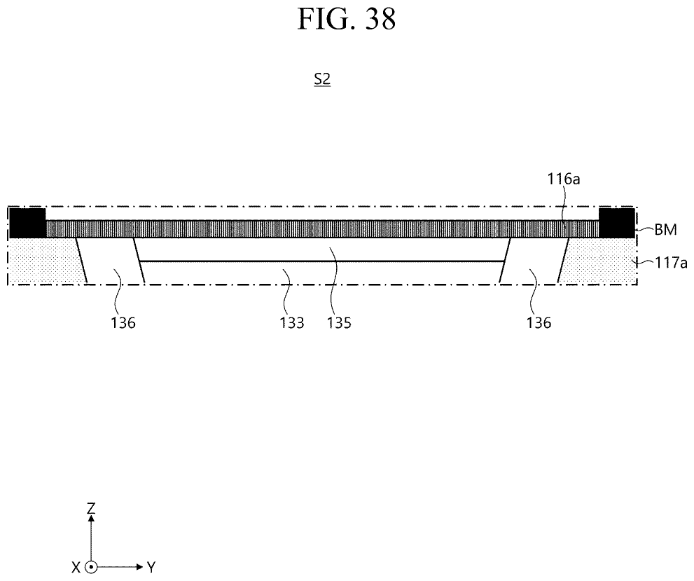

FIGS. 37 and 38 are partially enlarged views (S1 and S2) showing portion S of FIG. 36 in an enlarged manner. FIGS. 37 and 38 each illustrate a display apparatus according to one of eighteenth and nineteenth embodiments.

As shown in FIGS. 37 and 38, in display apparatuses S1 and S2 according to the eighteenth embodiment and the nineteenth embodiment, a first passivation layer 116a may be disposed on a first optical layer 117a. A black matrix BM may be disposed on the first passivation layer 116a. The black matrix BM may be disposed around the first passivation layer 116a or on an edge thereof.

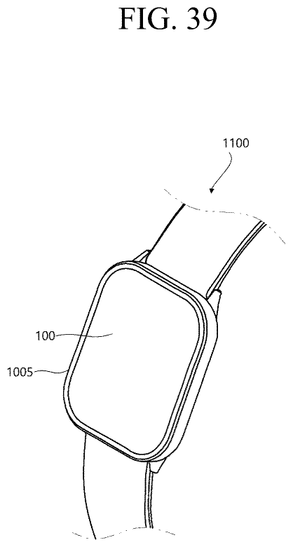

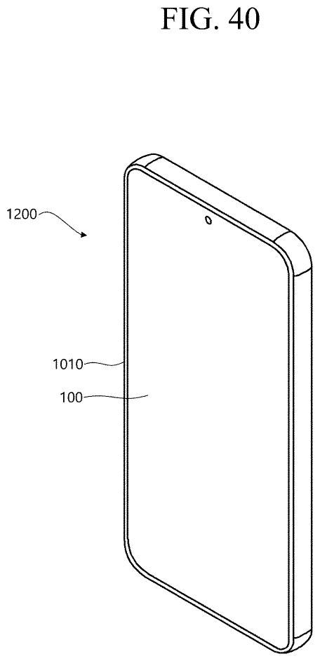

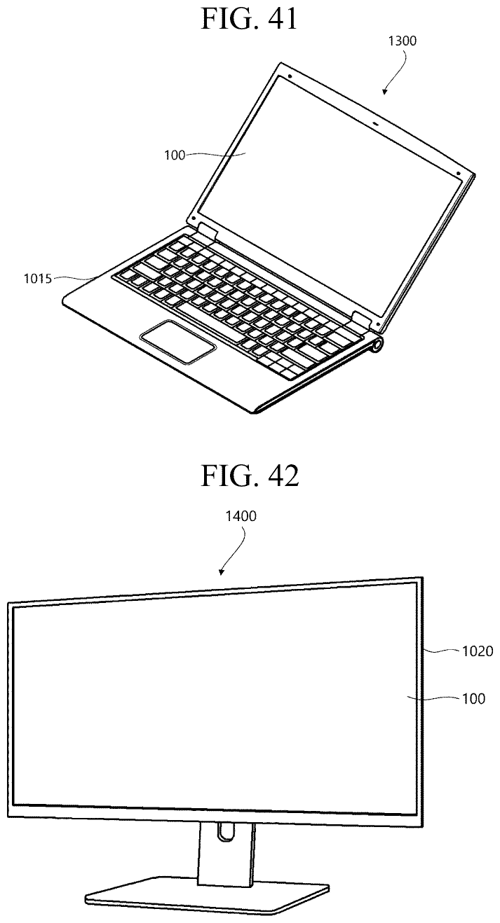

FIGS. 39 to 42 are views illustrating devices to which the display apparatus according to example embodiments of the present specification can be applied.

As shown in FIGS. 39 to 42, the display apparatus 1000 according to example embodiments of the present specification may be included in various devices or electronic devices. For example, As shown in FIGS. 39 to 42, various electronic devices may include a wearable device 1100, a mobile device 1200, a laptop 1300, and a monitor or TV 1400, but the embodiments of the present specification are not limited thereto.

The wearable device 1100, the mobile device 1200, the laptop 1300, and the monitor or TV 1400 may include case portions 1005, 1010, 1015, and 1020, respectively, and the display panel 100 and the display apparatus 1000 according to the embodiments of the present specification described above.

For example, the display apparatus according to an embodiment of the present specification may be applied to a mobile device, a video phone, a smartwatch, a watch phone, a wearable apparatus, a foldable apparatus, a rollable apparatus, a bendable apparatus, a flexible apparatus, a curved apparatus, a sliding apparatus, a variable apparatus, an electronic organizer, an electronic book, a portable multimedia player (PMP), a personal digital assistant (PDA), an MP3 player, a mobile medical apparatus, a desktop PC, a laptop PC, a netbook computer, a workstation, a navigation, a vehicle display apparatus, a theater display apparatus, a TV, a wallpaper apparatus, a signage apparatus, a game apparatus, a laptop, a monitor, a camera, a camcorder, a home appliance, etc.

A display apparatus according to various example embodiments of the present specification may be described as below.

A display apparatus according to various embodiments of the present specification may include a substrate including a display area including a plurality of pixels and a non-display area present around the display area, one or more pixel driving circuits disposed on the substrate, a plurality of inorganic light emitting diodes connected to the one or more pixel driving circuits, an optical layer present around the plurality of inorganic light emitting diodes, and a first passivation layer disposed on the optical layer.

According to various embodiments of the present specification, the display apparatus may further include a black matrix disposed on the first passivation layer.

According to various embodiments of the present specification, the display apparatus may further include a second passivation layer disposed between the one or more pixel driving circuits and the plurality of inorganic light emitting diodes.

According to various embodiments of the present specification, a thickness of the first passivation layer may be different from a thickness of the second passivation layer.

According to various embodiments of the present specification, the display apparatus may further include a plurality of banks disposed between the one or more pixel driving circuits and the second passivation layer.

According to various embodiments of the present specification, the display apparatus may further include a pattern layer disposed between the plurality of banks and the plurality of inorganic light emitting diodes. The second passivation layer may include a hole through which the pattern layer is exposed.

According to various embodiments of the present specification, the display apparatus may further include a plurality of first electrodes disposed between the plurality of banks and the pattern layer.

According to various embodiments of the present specification, the display apparatus may further include a trench present around the display area and in the non-display area.

According to various embodiments of the present specification, the non-display area may include a dummy area including a dummy pixel.

According to various embodiments of the present specification, the non-display area may include a plurality of dummy light emitting diodes. The trench may be disposed between the plurality of dummy light emitting diodes.

According to various embodiments of the present specification, the first passivation layer may be disposed on the trench.

According to various embodiments of the present specification, the plurality of inorganic light emitting diodes may include an anode electrode, a first semiconductor layer disposed on the anode electrode, an active layer disposed on the first semiconductor layer, a second semiconductor layer disposed on the active layer, and a cathode electrode disposed on the second semiconductor layer.

According to various embodiments of the present specification, the plurality of inorganic light emitting diodes may have a vertical type structure.

According to various embodiments of the present specification, the plurality of inorganic light emitting diodes may further include a first electrode present at a lower portion of the plurality of inorganic light emitting diodes and to which the anode electrode is electrically connected and a pattern layer present between the first electrode and the anode electrode. The first electrode and the anode electrode may be electrically connected through eutectic bonding by the pattern layer.

According to various embodiments of the present specification, the display apparatus may further include a plurality of connection lines disposed on the one or more pixel driving circuits and connected to the one or more pixel driving circuits. The plurality of connection lines may be spaced from each other and disposed on the same layer.

According to various embodiments of the present specification, the display apparatus may further include a plurality of connection lines disposed on the one or more pixel driving circuits and connected to the one or more pixel driving circuits and a plurality of insulating layers present between the plurality of connection lines. The plurality of connection lines may be disposed alternately with each other on different layers with the plurality of insulating layers disposed therebetween.

According to various embodiments of the present specification, the display apparatus may further include a bending area extending from the non-display area. An insulating layer adjacent to the plurality of banks each present on one of the plurality of inorganic light emitting diodes among the plurality of insulating layers may not be disposed in the bending area.

According to various embodiments of the present specification, a thickness of the insulating layer adjacent to the plurality of banks each present on one of the plurality of inorganic light emitting diodes among the plurality of insulating layers and a thickness of an insulating layer present on the one or more pixel driving circuits may each be thicker than a thickness of an insulating layer present between the plurality of banks and the one or more pixel driving circuits.

According to various embodiments of the present specification, the display apparatus may further include a plurality of pad electrodes connected to the one or more pixel driving circuits and another connection line connected to the plurality of pad electrodes and the one or more pixel driving circuits.

According to various embodiments of the present specification, the another connection line may be present on the same layer as a connection line present on the one or more pixel driving circuits among the plurality of connection lines.

A display apparatus according to various embodiments of the present specification may include a display panel made of a plurality of pixels including a plurality of light emitting diodes and a trench present on the plurality of pixels. The trench may include a first trench disposed between the plurality of light emitting diodes and a second trench disposed between the plurality of light emitting diodes.

According to various embodiments of the present specification, the first trench may be disposed to extend in a first direction. The second trench may be disposed to extend in a second direction intersecting the first direction.

According to various embodiments of the present specification, the display apparatus may further include a bending area disposed in the first direction from the display panel. The trench may further include a third trench disposed between the display panel and the bending area.

According to various embodiments of the present specification, the third trench may be disposed to extend in the second direction intersecting the first direction.

According to various embodiments of the present specification, the plurality of light emitting diodes may include a plurality of first light emitting diodes implementing a first color, a plurality of second light emitting diodes implementing a second color, and a plurality of third light emitting diodes implementing a third color. The first trench may be disposed between the plurality of first light emitting diodes and the plurality of second light emitting diodes.

According to various embodiments of the present specification, the display apparatus may further include an optical layer present on the plurality of light emitting diodes and a first passivation layer disposed on the optical layer. The first passivation layer may be disposed on the trench.

A display apparatus according to various embodiments of the present specification may include a substrate including a display area and a non-display area present around the display area, a plurality of light emitting diodes present in the display area, a plurality of dummy light emitting diodes present in the non-display area, a first passivation layer disposed on the plurality of light emitting diodes and the plurality of dummy light emitting diodes, and a trench disposed between the plurality of dummy light emitting diodes.

According to various embodiments of the present specification, the display apparatus may further include an optical layer present on the plurality of light emitting diodes or the plurality of dummy light emitting diodes. The optical layer may include the trench. The first passivation layer may be disposed on the trench.

According to various embodiments of the present specification, the optical layer may include a first optical layer present on the plurality of light emitting diodes and the plurality of dummy light emitting diodes and a second optical layer present on the plurality of light emitting diodes.

According to various embodiments of the present specification, the display apparatus may further include a black matrix disposed on the first passivation layer.

According to various embodiments of the present specification, the plurality of light emitting diodes may be disposed between a plurality of first electrodes and a plurality of second electrodes disposed on the plurality of first electrodes. The plurality of dummy light emitting diodes may be disposed on the plurality of first electrodes.

According to various embodiments of the present specification, the first passivation layer may be disposed on the second electrode.

According to various embodiments of the present specification, the display apparatus may further include a pattern layer disposed between the plurality of first electrodes and the plurality of light emitting diodes.

According to various embodiments of the present specification, the plurality of first electrodes and the plurality of light emitting diodes may be connected through eutectic bonding by the pattern layer.

According to the present specification, since a display apparatus can be protected from penetration of moisture from the outside, the reliability of the display apparatus can be improved.

Since permeation of moisture into a display apparatus from the outside can be prevented or suppressed, the service life of the display apparatus can be improved. Thus, it is possible to provide a display apparatus whose power consumption is reduced and which can be operated with low power.

The probability of defective transfer of light emitting diodes can be reduced in a process of manufacturing a display panel. Thus, productivity of a display apparatus can be improved.

Effects of the present specification are not limited to those mentioned above, and other unmentioned effects should be clearly understood by those of ordinary skill in the art to which the technical spirit of the present specification pertains from the content described herein.

Although various embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept or scope of the present disclosure. The scope of the technical concept of the present disclosure is not limited thereto. Therefore, it should be understood that the above-described example embodiments are illustrative in all aspects and do not limit the present disclosure. The protective scope of the present disclosure may be construed based on the following claims and their equivalents, and all the technical concepts in the equivalent scope thereof should be construed as falling within the scope of the present disclosure.

What is claimed is:

1. A display apparatus, comprising:
a substrate including a display area including a plurality of pixels and a non-display area disposed around the display area;
one or more pixel driving circuits disposed on the substrate;
a plurality of inorganic light emitting diodes connected to the one or more pixel driving circuits;
an optical layer disposed around the plurality of inorganic light emitting diodes;
a first passivation layer disposed on the optical layer; and
a trench disposed between the plurality of inorganic light emitting diodes.

2. The display apparatus of claim 1, further comprising:
a black matrix disposed on the first passivation layer; and
a second passivation layer disposed between the one or more pixel driving circuits and the plurality of inorganic light emitting diodes.

3. The display apparatus of claim 2, further comprising a plurality of banks disposed between the one or more pixel driving circuits and the second passivation layer.

4. The display apparatus of claim 3, further comprising a pattern layer disposed between the plurality of banks and the plurality of inorganic light emitting diodes,
wherein the second passivation layer includes a hole through which the pattern layer is exposed.

5. The display apparatus of claim 4, further comprising a plurality of first electrodes disposed between the plurality of banks and the pattern layer.

6. The display apparatus of claim 1, wherein the trench is disposed around the display area and in the non-display area.

7. The display apparatus of claim 6, wherein the non-display area includes a dummy area including a dummy pixel.

8. The display apparatus of claim 6, wherein:
the non-display area includes a plurality of dummy light emitting diodes; and
the trench is disposed between the plurality of dummy light emitting diodes.

9. The display apparatus of claim 1, wherein the plurality of inorganic light emitting diodes include:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

10. The display apparatus of claim 9, wherein the plurality of inorganic light emitting diodes further include:
a first electrode disposed at a lower portion of the plurality of inorganic light emitting diodes and to which the anode electrode is electrically connected; and
a pattern layer disposed between the first electrode and the anode electrode, and
wherein the first electrode and the anode electrode are electrically connected through eutectic bonding by the pattern layer.

11. The display apparatus of claim 1, further comprising a plurality of connection lines disposed on the one or more pixel driving circuits and connected respectively to the one or more pixel driving circuits,
wherein the plurality of connection lines are spaced from each other and disposed on the same layer.

12. The display apparatus of claim 1, further comprising:
a plurality of connection lines disposed on the one or more pixel driving circuits and connected respectively to the one or more pixel driving circuits; and
a plurality of insulating layers disposed between the plurality of connection lines,
wherein the plurality of connection lines are disposed alternately with each other on different layers with the plurality of insulating layers disposed therebetween.

13. The display apparatus of claim 12, further comprising a bending area extending from the non-display area,
wherein an insulating layer adjacent to a plurality of banks each disposed on a corresponding one of the plurality of inorganic light emitting diodes, among the plurality of insulating layers, is not disposed in the bending area.

14. The display apparatus of claim 13, wherein, among the plurality of insulating layers, the insulating layer adjacent to the plurality of banks each disposed on the corresponding one of the plurality of inorganic light emitting diodes and an insulating layer disposed on the one or more pixel driving circuits are each thicker than an insulating layer disposed between the plurality of banks and the one or more pixel driving circuits.

15. The display apparatus of claim 11, further comprising:
a plurality of pad electrodes connected to the one or more pixel driving circuits; and
another connection line connected to the plurality of pad electrodes and the one or more pixel driving circuits.

16. The display apparatus of claim 15, wherein the other connection line is disposed on the same layer as a connection line disposed on the one or more pixel driving circuits among the plurality of connection lines.

17. The display apparatus of claim 7, further comprising:
a bank;
a first electrode disposed on the bank, the inorganic light emitting diodes being disposed on the bank and the first electrode; and
a second electrode disposed on the inorganic light emitting diodes,
wherein the second electrode is not disposed in the dummy area.

18. A display apparatus, comprising:
a display panel having a plurality of pixels including a plurality of light emitting diodes; and
a trench disposed on the plurality of pixels,
wherein the trench includes a first trench disposed between the plurality of light emitting diodes and a second trench disposed between the plurality of light emitting diodes.

19. The display apparatus of claim 18, wherein:
the first trench is disposed to extend in a first direction; and
the second trench is disposed to extend in a second direction intersecting the first direction.

20. A display apparatus, comprising:
a substrate including a display area and a non-display area disposed around the display area;
a plurality of light emitting diodes disposed in the display area;
a plurality of dummy light emitting diodes disposed in the non-display area;
a first passivation layer disposed on the plurality of light emitting diodes and the plurality of dummy light emitting diodes; and
a trench disposed in the non-display area and disposed between the plurality of dummy light emitting diodes.
